(19) United States
(12) Patent Application Publication
(10) Pub. No.: US 2025/0093556 A1
(43) Pub. Date: Mar. 20, 2025

(54) LIGHT DIFFUSION FILM, POLARIZER AND DISPLAY DEVICE

(71) Applicant: TCL CHINA STAR OPTOELECTRONICS TECHNOLOGY CO., LTD., Shenzhen (CN)

(72) Inventor: Yue WANG, Shenzhen (CN)

(21) Appl. No.: 18/384,877

(22) Filed: Oct. 29, 2023

(30) Foreign Application Priority Data
Sep. 20, 2023 (CN) 202311214751.9

(51) Int. Cl. G02B 5/02; G02B 5/30

(52) U.S. Cl. CPC G02B 5/0242; G02B 5/305

(57) ABSTRACT

An embodiment of the present application discloses a light diffusion film including a substrate and light diffusion particles dispersed in the substrate, wherein a mass fraction of the light diffusion particles in the substrate is less than 3%. According to the present application, by adding the light diffusion particles having a mass fraction less than 3% to the substrate of the light diffusion film, the viewing angle of the polarizer can be improved.

### CROSS-REFERENCE OF RELATED APPLICATION

This application claims priority to Chinese Patent Application No. 202311214751.9, filed on Sep. 20, 2023, which is hereby incorporated by reference in its entirety.

### TECHNICAL FIELD

The present application relates to the field of display technologies, and more particularly, to a light diffusion film, a polarizer, and a display device.

### BACKGROUND

Currently, to enlarge a chromaticity viewing angle of a display device, an optical film is usually provided on an outermost side of a polarizer. According to a conventional optical film for enlarging the chromaticity viewing angle, a film layer (for example, a layer formed by a patterned high-refractive layer overlapped with a low-refractive layer) needs to be added to the polarizer, which is complicated in process and results in an increase in a thickness of the polarizer and a decrease in outgoing lights of the display device, thereby deteriorating display contrast of the display device.

Accordingly, there is a need for a light diffusion film, a polarizer, and a display device.

### SUMMARY

The present application provides a light diffusion film, a polarizer, and a display device, which can alleviate technical problems of deterioration of display contrast of a display device due to adding a film layer to a polarizer and reducing outgoing lights from the display device.

The present application provides a light diffusion film including: a substrate; and light diffusion particles dispersed in the substrate; wherein a mass fraction of the light diffusion particles in the substrate is less than 3%.

In an embodiment, the light diffusion particles include first light diffusion particles; wherein the first light diffusion particles have a plurality of first cross-sections, each of the first cross-sections has a first circumcircle, a ratio of a length of a major axis of the first light diffusion particle to a diameter of a greatest first circumcircle of the first light diffusion particle is greater than or equal to 5, and less than 100, and the first cross-section is perpendicular to an extension direction of the major axis of the first light diffusion particle.

In an embodiment, the first light diffusion particles are selected from at least one of a first subtype light diffusion particle, a second subtype light diffusion particle, a third subtype light diffusion particle, a fourth subtype light diffusion particle, and a fifth subtype light diffusion particle having different shapes from each other.

In an embodiment, a variation value of diameters of first circumcircles of first cross-sections of the first subtype light diffusion particle is less than or equal to 0.3 μm along an extension direction of a major axis of the first subtype light diffusion particle.

In an embodiment, a variation value of diameters of first circumcircles of first cross-sections at a middle portion of the second subtype light diffusion particle is less than or equal to 1 μm along an extension direction of a major axis of the second subtype light diffusion particle; in a direction away from the middle portion of the second subtype light diffusion particle, a variation value of diameters of first circumcircles of first cross-sections at a first end portion of the second subtype light diffusion particle gradually decrease, and a variation value of diameters of first circumcircles of first cross-sections at a second end portion of the second subtype light diffusion particle is less than or equal to 1 μm.

In an embodiment, a variation value of diameters of first circumcircles of first cross-sections at a middle portion of the third subtype light diffusion particle is less than or equal to 1 μm along an extension direction of a major axis of the third subtype light diffusion particle; in a direction away from the middle portion of the third subtype light diffusion particle, a variation value of diameters of first circumcircles of first cross-sections at a first end portion of the third subtype light diffusion particle gradually decrease, and a variation value of diameters of first circumcircles of first cross-sections at a second end portion of the third subtype light diffusion particle gradually decrease.

In an embodiment, a first end portion of the fourth subtype light diffusion particle is connected to a second end portion of the fourth subtype light diffusion particle, and diameters of first circumcircles of first cross-sections of the fourth subtype light diffusion particle gradually decrease in a direction from the first end portion of the fourth subtype light diffusion particle to the second end portion of the fourth subtype light diffusion particle.

In an embodiment, a first end portion of the fifth subtype light diffusion particle is connected to a second end portion of the fifth subtype light diffusion particle, diameters of first circumcircles of first cross-sections at the first end portion of the fifth subtype light diffusion particle gradually decrease in a direction away from the second end portion of the fifth subtype light diffusion particle, and diameters of first circumcircles of first cross-sections at the second end portion of the fifth subtype light diffusion particle gradually decrease in a direction away from the first end portion of the fifth subtype light diffusion particle.

In an embodiment, the light diffusion particles further include second light diffusion particles; wherein the second light diffusion particles have a plurality of second cross-sections, each of the second cross-sections has a second circumcircle, a ratio of a length of a major axis of the second light diffusion particle to a diameter of a greatest second circumcircle is greater than or equal to 1, and less than 5, and the second cross-section is perpendicular to an extension direction of the major axis of the second light diffusion particle.

In an embodiment, the second light diffusion particles are selected from at least one of a sixth subtype light diffusion particle, a seventh subtype light diffusion particle, an eighth subtype light diffusion particle, a ninth subtype light diffusion particle, and a tenth subtype light diffusion particle having different shapes from each other.

In an embodiment, a variation value of diameters of second circumcircles of second cross-sections of the sixth subtype light diffusion particle is less than or equal to 0.3 μm along an extension direction of a major axis of the sixth subtype light diffusion particle.

In an embodiment, a first end portion of the seventh subtype light diffusion particle is connected to a second end portion of the seventh subtype light diffusion particle, diameters of second circumcircles of second sections at the first end portion of the seventh subtype light diffusion particle gradually decrease in a direction away from the second end portion of the seventh subtype light diffusion particle, and diameters of second circumcircles of second cross-sections at the second end portion of the seventh subtype light diffusion particle gradually decrease in a direction away from the first end portion of the seventh subtype light diffusion particle.

In an embodiment, a variation value of diameters of second circumcircles of second cross-sections at a middle portion of the eighth subtype light diffusion particle is less than or equal to 1 μm along an extension direction of a major axis of the eighth subtype light diffusion particle; in a direction away from the middle portion of the eighth subtype light diffusion particle, a variation value of diameters of second circumcircles of second cross-sections at a first end portion of the eighth subtype light diffusion particle gradually decrease, and a variation value of diameters of second circumcircles of second cross-sections at a second end portion of the eighth subtype light diffusion particle is less than or equal to 1 μm.

In an embodiment, a variation value of diameters of second circumcircles of second cross-sections at a middle portion of the ninth subtype light diffusion particle is less than or equal to 1 μm along an extension direction of a major axis of the ninth subtype light diffusion particle; in a direction away from the middle portion of the ninth subtype light diffusion particle, a variation value of diameters of second circumcircles of second cross-sections at a first end portion of the ninth subtype light diffusion particle gradually decrease, and a variation value of diameters of second circumcircles of second cross-sections at a second end portion of the ninth subtype light diffusion particle gradually decrease.

In an embodiment, a first end portion of the tenth subtype light diffusion particle is connected to a second end portion of the tenth subtype light diffusion particle, and diameters of second circumcircles of second cross-sections of the tenth subtype light diffusion particle gradually decrease in a direction from the first end portion of the tenth subtype light diffusion particle to the second end portion of the tenth subtype light diffusion particle.

In an embodiment, the first subtype light diffusion particle is selected from a rod-shaped particle, the second subtype light diffusion particle is selected from an acicular particle having a reduced diameter from an end to another, the third subtype light diffusion particle is selected from an acicular particle having a reduced diameter from middle to both ends, the fourth subtype light diffusion particle is selected from a long cone-shaped particle, the fifth subtype light diffusion particle is selected from a bicone-shaped particle and/or an ellipsoid-shaped particle, the sixth subtype light diffusion particle is selected from a cubic particle or a cuboid-shaped particle, the seventh subtype light diffusion particle is selected from a spherical particle or an ellipsoid-shaped particle, the eighth subtype light diffusion particle is selected from an acicular particle having reduced diameters from middle to an end, the ninth subtype light diffusion particle is selected from an acicular particle having reduced diameters from middle to both ends, and the tenth subtype light diffusion particle is selected from a long cone-shaped particle.

In an embodiment, a mass fraction of the fifth subtype light diffusion particles in the light diffusion particles is greater than or equal to 20%, and a mass fraction of the fifth subtype light diffusion particles in the light diffusion particles is less than or equal to 100%.

In an embodiment, each of the light diffusion particles has an average particle size, a length of ta major axis of the light diffusion particle is greater than or equal to 20% of the average particle size of the light diffusion particle, and the length of the in major axis of the light diffusion particle is less than or equal to 180% of the average particle size of the light diffusion particle.

In an embodiment, the substrate includes a first sub-substrate selected from at least one of an unmodified polyester, an unmodified acetate fiber, and/or a second sub-substrate selected from at least one of a modified polyester, a modified cellulose acetate; wherein a mass fraction of the first sub-substrate in the substrate is greater than or equal to 65%, and the mass fraction of the first sub-substrate in the substrate is less than or equal to 100%; and a mass fraction of the second sub-substrate in the substrate is greater than or equal to 0%, and the mass fraction of the second sub-substrate in the substrate is less than or equal to 35%.

The present application further provides a polarizer including the light diffusion film described above.

The present application further provides a display device including the polarizer as above.

### BRIEF DESCRIPTION OF THE DRAWINGS

In order that the technical solution in the embodiments of the present application may be more clearly described, reference is made briefly to the drawings required for the description of the embodiments, and it should be understood that the drawings in the description below are only for some of the embodiments of the present application, and other drawings may be made to those skilled in the art without involving any inventive effort.

FIG. 1 is a first schematic structural diagram of a light diffusion film according to an embodiment of the present application;

FIG. 2 is a second schematic structural diagram of a light diffusion film according to an embodiment of the present application;

FIG. 3 is a first schematic structural diagram of a polarizer according to an embodiment of the present application;

FIG. 4 is a second schematic structural diagram of a polarizer according to an embodiment of the present application;

FIG. 5 is a third schematic structural diagram of a polarizer according to an embodiment of the present application;

FIG. 6 is a fourth schematic structural diagram of a polarizer according to an embodiment of the present application;

FIG. 7 is a first schematic structural diagram of a display device according to an embodiment of the present application;

FIG. 8a is a cross-section of the first light diffusion particle and the fifth light diffusion particle;

FIG. 8b is a schematic structural diagram of a first subtype light diffusion particle and a fifth subtype light diffusion particle according to an embodiment of the present application;

FIG. 8c is a schematic structural diagram of a second subtype light diffusion particle and a seventh subtype light diffusion particle according to an embodiment of the present application;

FIG. 8d is a schematic structural diagram of a third subtype light diffusion particle and a ninth subtype light diffusion particle according to an embodiment of the present application;

FIG. 8e is a schematic structural diagram of a fourth subtype light diffusion particle and a tenth subtype light diffusion particle according to an embodiment of the present application; and

FIG. 8f is a schematic structural diagram of a fifth subtype light diffusion particle and an eighth subtype light diffusion particle according to an embodiment of the present application.

### DETAILED DESCRIPTION OF THE EMBODIMENTS

The technical solution in the embodiments of the present application are described more clearly and completely with reference to the drawings. It should be understood that the described embodiments are merely a part of the application, and based on the embodiments of the present application, all other embodiments obtained by a person skilled in the art without involving any inventive effort are within the scope of the present application. Furthermore, it should be understood that the embodiments described herein are merely illustrative and explanatory of the application and are not intended to limit the application. In the present application, if not stated to the contrary, the use of positional terms such as “on” and “under” refer to “on” or “under” the device in use or operation; specifically, refer to the direction in the drawings. Moreover, the terms “in” and “out” are for the outline of the device.

Currently, a film layer needs to be added to a polarizer of a conventional optical film for enlarging the chromaticity viewing angle. As such, outgoing lights of a display device is reduced and display contrast is deteriorated, resulting in a technical problem that display quality of the display device is degraded.

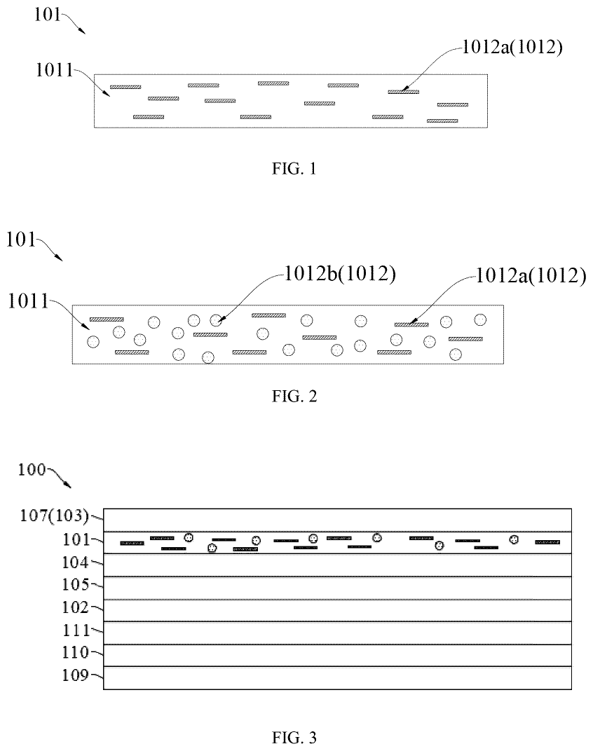

Referring to FIGS. 1 to 2, an embodiment of the present application provides a light diffusion film 101 including a substrate 1011, and light diffusion particles 1012 dispersed in the substrate 1011. Mass fraction of the light diffusion particles 1012n the substrate 1011 is less than 3%.

According to the embodiment of the present application, by adding the light diffusion particles 1012 having a mass fraction of less than 3% to the substrate 1011 of the light diffusion film 101, the viewing angle of the polarizer can be increased by refraction of the lights by the light diffusion particles 1012. As such, no additional film layer is needed for the polarizer, thereby preventing the outgoing lights from being reduced, improving the chromaticity angle of view and the contrast of the display device having the light diffusion film 101, and increasing the light outgoing rate of the display device.

The embodiments and examples are provided following for describing the present application.

Referring to FIGS. 1 to 2, in an embodiment, each of the light diffusion particle 1012 has a major axis and a diameter. The length of the major axis of the light diffusion particle 1012 is a distance between two ends of the major axis of the light diffusion particle 1012. Each light diffusion particle 1012 has a plurality of cross-sections perpendicular to an extension direction of the major axis of the light diffusion particle 1012, each of the cross-sections has a circumcircle, and the diameter of the light diffusion particle 1012 refers to the diameter of the greatest circumcircle corresponding to the plurality of cross-sections. Two farthest points of the light diffusion particle 1012 in the cross-section are located on the circumcircle of the cross-section, and the distance between the two farthest points of the light diffusion particle 1012 in the cross-section is the diameter of the circumcircle. The light diffusion particles 1012 include first light diffusion particles 1012a.

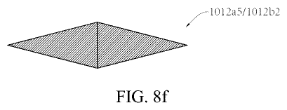

As shown in FIG. 8a, ach of the first light diffusion particles 1012a has a plurality of first cross-sections 1013, and each of the first cross-sections 1013 has a first circumcircle 1013a. FIG. 8a is indicated to show the relation between the first cross-section 1013 and the first circumcircle 1013a, and the shape of the first cross-section 1013 is not limited as FIG. 8a. A ratio of the length of the major axis of the first light diffusion particle 1012a to the diameter of the greatest first circumcircle is greater than or equal to 5, and the ratio of the length of the major axis of the first light diffusion particle 1012a to the diameter of the greatest first circumcircle is less than 100, for example, the ratio may be 10, 12, 15, 16, 18, 20, 30, 32, 34, 35, 36, 38, 40, 42, 45, 46, 48, 50, 52, 55, 56, 58, 60, 62, 65, 68, 70, 80, 90 and the like. Further, the first cross-section is perpendicular to the extension direction of the major axis of the first light diffusion particle 1012a. The diameter of the first circumcircle of one first cross-section of the first light diffusion particle 1012a is a distance between two farthest points of the one first cross-section. By using the first light diffusion particle 1012a having a greater length-to-diameter ratio (ratio of a length of a major axis to a diameter of the greatest first circumcircle), it is easier to change the propagation direction of more lights through the light diffusion particles 1012, thereby obtaining an improved effect of the light diffusion particles 1012 on the chromaticity viewing angle and the contrast.

In some embodiments, referring to FIGS. 8b-8f, the first light diffusion particles 1012 as are selected from at least one of first subtype light diffusion particles 1012a1, second subtype light diffusion particles 1012a2, third subtype light diffusion particles 1012a3, fourth subtype light diffusion particles 1012a4, and fifth subtype light diffusion particles 1012a5 having different shapes from each other. It should be noted that, the first subtype light diffusion particles 1012a1, the second subtype light diffusion particles 1012a2, the third subtype light diffusion particles 1012a3, the fourth subtype light diffusion particles 1012a4, and the fifth subtype light diffusion particles 1012a5 each have a first cross-section and a first circumcircle. The first cross-section and the first circumcircle can refer to FIG. 8a, however, FIG. 8a is indicated to show the relation between the first cross-section and the first circumcircle, and the shape of the first cross-section is not limited as FIG. 8a.

As shown in FIG. 8b, a variation value of the diameters of the first circumcircles of the first cross-section of the first subtype light diffusion particle 1012a1 is less than or equal to 0.3 μm, for example, 0 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the extension direction of the major axis of the first subtype light diffusion particle 1012a1. In some embodiments, along the extension direction of the major axis of the first subtype light diffusion particle 1012a1, the diameters of the first circumcircles of the first cross-sections at the first end portion of the first subtype light diffusion particle 1012a1 are the same as the diameters of the first circumcircles of the first cross-sections at the middle portion of the first subtype light diffusion particle 1012a1, and the diameters of the first circumcircles at the second end portion of the first subtype light diffusion particle are the same as the diameters of the first circumcircles at the middle portion of the first subtype light diffusion particle 1012a1.

In some embodiments, the first cross-section of the first subtype light diffusion particle 1012a1 may have a regular shape or an irregular shape, wherein the regular shape includes a circle, an ellipse, a triangle, a quadrilateral, or the like.

In some embodiments, the first subtype light diffusion particles 1012a1 may be rod-shaped particles, and the first cross-sections of the first subtype light diffusion particles 1012a1 are circular or elliptical. In a case that the first cross-sections of the first subtype light diffusion particles 1012a1 are circular, the first circumcircles of the first cross-sections of the first subtype light diffusion particles 1012a1 may coincide with the first cross-sections. In a case that the first cross-sections of the first subtype light diffusion particles 1012a1 are elliptical, the diameter of the first circumcircle of each of the first cross-sections of the first subtype light diffusion particle 1012a1 is a length of the major axis of any elliptical first cross-section of the first subtype light diffusion particle 1012a1, and a ratio of the major axis of the elliptical first cross-section of the first subtype light diffusion particle 1012a1 to the minor axis of the elliptical first cross-section of the first subtype light diffusion particle 1012a1 is greater than 1 and less than or equal to 3, for example, may be 1.2, 1.5, 1.8, 2, 2.2, 2.5, 2.8, or the like.

It should be noted that, the major axis of the light diffusion particle refers to the horizontal direction in FIG. 8b-8f, and the minor axis of the light diffusion particle refers to the vertical direction in FIG. 8b-8f. Moreover, the first end portion refers to the right portion of the light diffusion particle shown in FIG. 8b-8f, the second end portion refers to the left portion of the light diffusion particle shown in FIG. 8b-8f, and the middle portion is between the first end portion and the second portion of the light diffusion particle shown in FIG. 8b-8f.

As shown in FIG. 8c, variation value of the diameters of the first circumcircles of the first cross-sections at the middle portion of the second subtype light diffusion particle 1012a2 is less than or equal to 1 μm, for example, may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48 μm, 0.45 μm, 0.42 μm, 0.4 μm, 0.38 μm, 0.35 μm, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the direction of the major axis of second subtype light diffusion particle 1012a2. The diameters of the first circumcircles of the first cross-sections at the first end portion of the second subtype light diffusion particle 1012a2 gradually decrease in a direction away from the middle portion of the second subtype light diffusion particle 1012a2, and a variation value of the diameters at the second end portion of the second subtype light diffusion particle 1012a2 is less than or equal to 1 μm, for example, may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48μ, 0.45μ, 0.42μ, 0.4 μm, 0.38 μm, 0.35μ, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like. In some embodiments, the diameters of the first circumcircles of the first cross-sections at the first end portion of the second subtype light diffusion particle 1012a2 gradually decrease in a direction away from the middle portion of the second subtype light diffusion particle 1012a2, and the diameters of the first circumcircles of the first cross-sections at the second end portion of the second subtype light diffusion particle 1012a2 are the same as the diameters of the first circumcircles of the first cross-sections at the middle portion of the second subtype light diffusion particle 1012a2.

It should be understood that the diameters of the first circumcircles of the first cross-sections at the first end portion of the second subtype light diffusion particle 1012a2 decrease gradually in a direction away from the middle portion of the second subtype light diffusion particle 1012a2, indicating that the diameters of the first circumcircles of the first cross-sections at the first end portion of the second subtype light diffusion particle 1012a2 have a tendency to decrease in a direction away from the middle portion of the second subtype light diffusion particle 1012a2, wherein the tendency includes but not limited to, the diameters of the first circumcircles of the first cross-sections at the first end portion of the second subtype light diffusion particle 1012a2 decreasing in sequence in a direction away from the middle portion of the second subtype light diffusion particle 1012a2.

In some embodiments, the first cross-section of the second subtype light diffusion particle 1012a2 may have a regular shape or an irregular shape, wherein the regular shape may be a circle, an ellipse, a triangle, a quadrilateral, or the like.

In some embodiments, the second subtype light diffusion particles 1012a2 may be acicular particles, and each of the acicular particles has diameters reduced from middle to an end.

In some embodiments, in a case that the second subtype light diffusion particle 1012a2 is acicular particle having diameters reduced from middle to an end, the first cross-sections of the second subtype light diffusion particle may be circular or elliptical. In a case that the first cross-sections at the second end portion of the second subtype light diffusion particle 1012a2 or the first cross-sections at the middle portion of the second subtype light diffusion particle 1012a2 are elliptical, the ratio of the long axis of any elliptical first cross-section at the second end portion or the middle portion of the second subtype light diffusion particle 1012a2 to the minor axis of the elliptical first cross-section is greater than 1 and less than or equal to 3, for example, may be 1.2, 1.5, 1.8, 2, 2.2, 2.5, 2.8, and the like. The shapes of the first cross-sections at first end portion of the second subtype light diffusion particle 1012a2 coincide with the shapes of the first cross-sections at the middle portion of the second subtype light diffusion particle 1012a2, and the areas of the first cross-sections gradually decrease in a direction away from the middle portion of the second subtype light diffusion particle 1012a2.

As shown in FIG. 8d, variation value of the diameters of the first circumcircles of the first cross-sections at the middle portion of the third subtype light diffusion particle 1012a3 is less than or equal to 1 μm, for example, may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48 μm, 0.45 μm, 0.42 μm, 0.4 μm, 0.38 μm, 0.35 μm, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the direction of the major axis of the third subtype light diffusion particle 1012a3. The diameters of the first circumcircles of the first cross-sections at the first end portion of the third subtype light diffusion particle 1012a3 gradually decrease, and the diameters of the first circumcircles of the first cross-sections at the second end portion of the third subtype light diffusion particle 1012a3 of the gradually decrease, in a direction away from the middle portion of the third subtype light diffusion particle 1012a3. In some embodiments, the first circumcircles of the first cross-sections at the middle portion of the third subtype light diffusion particle 1012a3 have uniform diameters along the extension direction of the major axis of the third subtype light diffusion particle 1012a3, and the diameters of the first circumcircles of the first cross-sections at the first end portion and second end portion of the third subtype light diffusion particle 1012a3 gradually change.

It should be understood that the diameters of the first circumcircles of the first cross-sections of the first end portion of the third subtype light diffusion particle 1012a3 decrease gradually in a direction away from the middle portion of the third subtype light diffusion particle 1012a3, indicating that the diameters of the first circumcircles of the first cross-sections at the first end portion of the third subtype light diffusion particle 1012a3 have a tendency to decrease in a direction away from the middle portion of the third subtype light diffusion particle 1012a3, wherein the tendency includes but not limited to, the diameters of the first circumcircles of the first cross-sections at the first end portion of the third subtype light diffusion particle 1012a3 decreasing in sequence in a direction away from the middle portion of the third subtype light diffusion particle 1012a3.

It should be understood that the diameters of the first circumcircles of the first cross-sections at the second end portion of the third subtype light diffusion particle 1012a3 decrease gradually in a direction away from the middle portion of the third subtype light diffusion particle 1012a3, indicating that the diameters of the first circumcircles of the first cross-sections at the second end portion of the third subtype light diffusion particle 1012a3 have a tendency to decrease in a direction away from the middle portion of the third subtype light diffusion particle 1012a3, wherein the tendency includes but not limited to, the diameters of the first circumcircles of the first cross-sections at the second end portion of the third subtype light diffusion particle 1012a3 decreasing in sequence in a direction away from the middle portion of the third subtype light diffusion particle 1012a3.

In some embodiments, the first cross-section of the third subtype light diffusion particle 1012a3 may be a regular shape or an irregular shape, wherein the regular shape may be a circle, an ellipse, a triangle, a quadrilateral, or the like.

In some embodiments, the third subtype light diffusion particles 1012a3 may be acicular particles, and each of the acicular particles has diameters reduced from middle to end.

In some embodiments, in a case that the third subtype light diffusion particle 1012a3 is an acicular particle having diameters reduced from middle to end, the first cross-sections of the third subtype light diffusion particles 1012a3 may be circular or elliptical. In a case that the first cross-sections at the middle portion of the third subtype light diffusion particle 1012a3 are elliptical, a ration of the major axis and the minor axis of any elliptical first cross-section at the middle portion of the third subtype light diffusion particle 1012a3 is greater than 1 and less than or equal to 3, for example, may be 1.2, 1.5, 1.8, 2, 2.2, 2.5, 2.8, and the like. The shapes of the first cross-sections at the first end portion and the second end portion of the third subtype light diffusion particle 1012a3 coincide with the shapes of the first cross-sections at the middle portion of the third subtype light diffusion particle 1012a3, and the areas of the first cross-sections gradually decrease in a direction away from the middle portion of the third subtype light diffusion particle 1012a3.

Referring to FIG. 8e, the first end portion of the fourth subtype light diffusion particle 1012a4 is connected to the second end portion of the fourth subtype light diffusion particle 1012a4, and the diameters of the first circumcircles of the first cross-sections of the fourth subtype light diffusion particle 1012a4 gradually decrease in a direction from the first end portion of the fourth subtype light diffusion particle 1012a4 to the second end portion of the fourth subtype light diffusion particle 1012a4.

It should be understood that the diameters of the first circumcircles of the first cross-sections of the fourth subtype light diffusion particle 1012a4 decrease gradually in the direction at the first end portion of the fourth subtype light diffusion particle 1012a4 toward the second end portion, indicating that the diameters of the first circumcircles of the first cross-sections of the fourth subtype light diffusion particle 1012a4 have a tendency to decrease in the direction of the first end portion of the fourth subtype light diffusion particle 1012a4 toward the second end portion, wherein the tendency includes but not limited to, the diameters of the first circumcircles of the first cross-sections of the fourth subtype light diffusion particle 1012a4 sequentially decreasing in a direction of the first end portion of the fourth subtype light diffusion particle 1012a4 toward the second end portion.

In some embodiments, the first cross-sections of the fourth subtype light diffusion particle 1012a4 may have a regular shape or an irregular shape, wherein the regular shape may be a circle, an ellipse, a triangle, a quadrilateral, or the like.

In some embodiments, the fourth subtype light diffusion particles may be long cone-shaped particles 1012a4.

In some embodiments, in a case that the fourth subtype light diffusion particles 1012a4 are long cone-shaped particles, the first cross-sections of the fourth subtype light diffusion particle 1012a4 may be circular or elliptical. In the direction of the first end portion of the fourth subtype light diffusion particle 1012a4 toward the second end portion of the fourth subtype light diffusion particle 1012a4, the first cross-sections of the fourth subtype light diffusion particle 1012a4 conform in shape and gradually decrease in area. In a case that the first cross-sections of the fourth subtype light diffusion particle 1012a4 are elliptical, the ratio of the major axis of any elliptical first cross-section of the fourth subtype light diffusion particle 1012a4 to the minor axis of the elliptical first cross-section is greater than 1 and less than or equal to 3, for example, may be 1.2, 1.5, 1.8, 2, 2.2, 2.5, 2.8, or the like.

Referring to FIG. 8f, the first end portion of the fifth subtype light diffusion particle 1012a5 is connected to the second end portion of the fifth subtype light diffusion particle 1012a5, and the diameters of the first circumcircles of the first cross-sections at the first end portion of the fifth subtype light diffusion particle 1012a5 gradually decrease in a direction away from the second end portion of the fifth subtype light diffusion particle 1012a5, and the diameters of the first circumcircles of the first cross-sections at the second end portion of the fifth subtype light diffusion particle 1012a5 gradually decrease in a direction away from the first end portion of the fifth subtype light diffusion particle 1012a5.

It should be understood that the diameters of the first circumcircles of the first cross-sections at the first end portion of the fifth subtype light diffusion particle 1012a5 gradually decrease in a direction away from the second end portion of the fifth subtype light diffusion particle, indicating that the diameters of the first circumcircles of the first cross-sections of the first end portion of the fifth subtype light diffusion particle 1012a5 have a tendency to decrease in a direction away from the second end portion of the fifth subtype light diffusion particle, wherein the tendency includes but not limited to, the diameters of the first circumcircles of the first end portion of the first cross-sections of the fifth subtype light diffusion particle 1012a5 decreasing in sequence in a direction away from the second end portion of the fifth subtype light diffusion particle 1012a5.

It should be understood that the diameters of the first circumcircles of the first cross-sections at the second end portion of the fifth subtype light diffusion particle 1012a5 gradually decrease in a direction away from the first end portion of the fifth subtype light diffusion particle 1012a5, indicating that the diameters of the first circumcircles of the first cross-sections at the second end portion of the fifth subtype light diffusion particle 1012a5 have a tendency to decrease in a direction away from the first end portion of the fifth subtype light diffusion particle 1012a5, wherein the tendency includes but not limited to, the diameters of the first circumcircles of the first cross-sections of the second portion of the light diffusion particle of the fifth subtype 1012a5 decreasing in sequence in a direction away from the first end portion of the fifth subtype light diffusion particle 1012a5.

In some embodiments, the first cross-sections of the fifth subtype light diffusion particle 1012a5 may have a regular shape or an irregular shape, wherein the regular shape may be a circle, an ellipse, a triangle, a quadrilateral, or the like.

In some embodiments, the fifth subtype light diffusion particles 1012a5 may be bipyramidal particles and/or ellipsoidal particles.

In some embodiments, in a case that the fifth subtype light diffusion particles 1012a5 may be bipyramidal particles and/or ellipsoidal particles, the first cross-sections of the fifth subtype light diffusion particle 1012a5 may be circular or elliptical. In a direction away from the second end portion of the fifth subtype light diffusion particle 1012a5, the first cross-sections of the first end portion of the fifth subtype light diffusion particle 1012a5 conform in shape and gradually decrease in area. In a direction away from the first end portion of the fifth subtype light diffusion particle 1012a5, the first cross-sections of the second end portion of the fifth subtype light diffusion particle 1012a5 conform in shape and gradually decrease in area. In a case that the first cross-sections of the fifth subtype light diffusion particle 1012a5 are elliptical, the ratio of the major axis of any elliptical first section of the fifth subtype light diffusion particle 1012a5 to the minor axis of the elliptical first section is greater than 1 and less than or equal to 3, and may be, for example, 1.2, 1.5, 1.8, 2, 2.2, 2.5, 2.8, or the like.

The fifth subtype light diffusion particles 1012a5 having a bipyramidal shape and an ellipsoidal shape differ in the following. In a case that the fifth subtype light diffusion particle 1012a5 is a bipyramidal particle, the fifth subtype light diffusion particle 1012a5 has a cross-section of a polygon such as a triangle or a quadrilateral parallel to the major axis. In a case that the fifth subtype light diffusion particle 1012a5 is an ellipsoidal particle, the fifth subtype light diffusion particle 1012a5 has an elliptical cross-section parallel to the major axis.

In some embodiments, the fifth subtype light diffusion particle 1012a5 may provide more propagation directions for the lights than the first subtype light diffusion particle 1012a1, the second subtype light diffusion particle 1012a2, the third subtype light diffusion particle 1012a3, and the fourth subtype light diffusion particle 1012a4, thereby improving the chromaticity viewing angle and the contrast. Thus, the first light diffusion particles 1012a include at least the fifth subtype light diffusion particles 1012a5. In the fifth subtype light diffusion particle 1012a5, the ellipsoidal particles are more advantageous than the bipyramidal particles in changing the direction propagation of lights. Preferably, the fifth subtype light diffusion particles include at least the ellipsoidal particles.

In some embodiments, the first light diffusion particles 1012a include the fifth subtype light diffusion particles, and the first light diffusion particles further includes at least one of the first subtype light diffusion particles, the second subtype light diffusion particles, the third subtype light diffusion particles, and the fourth subtype light diffusion particles. Preferably, the first light diffusion particles include the first subtype light diffusion particles, the second subtype light diffusion particles, the third subtype light diffusion particles, the fourth subtype light diffusion particles, and the fifth subtype light diffusion particles, as such the diversity of the shapes of the light diffusion particles 1012 is increased, the optical anisotropy of the light diffusion particles 1012 is increased, and the enhancement effect of the light diffusion particles 1012 on contrast and brightness is improved.

In some embodiments, the first light diffusion particle 1012a has a major axis length greater than or equal to 4 μm, and less than or equal to 30 μm, for example, the major axis may be 5 μm, 10 μm, 15 μm, 20 μm, 25 μm, and the like, in order to change the propagation direction of more lights through the major axis surfaces of the first light diffusion particles 1012a, thereby improving the enhancement effect of the light diffusion particles 1012 on contrast and brightness. Preferably, the length of the major axis of the first light diffusion particle 1012a is greater than or equal to 10 μm, and less than or equal to 30 μm, so as to obtain the first light diffusion particles 1012a having a suitable length of the major axis and being more concentrated, thereby contributing to further improving the enhancement effect of the light diffusion particles 1012 on contrast and brightness.

In some embodiments, the light diffusion particles 1012 may include the first light diffusion particles 1012a.

In some embodiments, while increasing the chromaticity viewing angle and contrast of the light diffusion film 101, the light diffusion particles 1012 further include the second light diffusion particles 1012b to improve the haze effect of the light diffusion film 101.

As shown in FIG. 8a, each of the second light diffusion particles 1012b have a plurality of second cross-sections 1014, and each of the second cross-sections 1014 has a second circumcircle 1014a. FIG. 8a is indicated to show the relation between the second cross-section 1014 and the second circumcircle 1014a, and the shape of the second cross-section 1014 is not limited as FIG. 8a. A ratio of the length of the major axis of the second light diffusion particle 1012b to the diameter of the greatest second circumcircle is greater than or equal to 1, and less than 5, for example, the ratio may be 1.1, 1.2, 1.3, 1.4, 1.5, 1.6, 1.7, 1.8, 1.9, 2, 2.2, 2.5, 2.8, 3, 3.5, 4, 4.5, and the like, wherein the second cross-section is perpendicular to the extension direction of the major axis of the second light diffusion particle 1012b. The light diffusion particles 1012 include the second-type light diffusion particles 1012b having a less length-to-diameter ratio (ratio of a length of a major axis to a diameter of the greatest second circumcircle), thereby improving the haze effect of the light diffusion film 101 while improving the chromaticity viewing angle and the contrast of the light diffusion film 101.

In some embodiments, referring to FIGS. 8b-8f, the second light diffusion particles 1012b are selected from at least one of sixth subtype light diffusion particles 1012b1, seventh subtype light diffusion particles 1012b2, eighth subtype light diffusion particles 1012b3, ninth subtype light diffusion particles 1012b4, and tenth subtype light diffusion particles 1012b5 having different shapes from each other. It should be noted that, the sixth subtype light diffusion particles 1012b1, the seventh subtype light diffusion particles 1012b2, the eighth subtype light diffusion particles 1012b3, the ninth subtype light diffusion particles 1012b4, and the tenth subtype light diffusion particles 1012b5 each have a second cross-section and a second circumcircle. The second cross-section and the second circumcircle can refer to FIG. 8a, however, FIG. 8a is indicated to show the relation between the second cross-section and the second circumcircle, and the shape of the second cross-section is not limited as FIG. 8a.

As shown in FIG. 8b, a variation value of the diameters of the second circumcircles of the second cross-sections of the sixth subtype light diffusion particle 1012b1 is less than or equal to 0.3 μm, for example, 0 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the extension direction of the major axis of the sixth subtype light diffusion particle 1012b1. In some embodiments, along the extension direction of the major axis of the sixth subtype light diffusion particle 1012b1, the diameters of the second circumcircles of the second cross-sections of the first end portion of the sixth subtype light diffusion particle 1012b1 are the same as the diameters of the second circumcircles of the second cross-sections of the middle portion of the sixth subtype light diffusion particle 1012b1, and the diameters of the second circumcircles of the second cross-sections of the second end portion of the sixth subtype light diffusion particle 1012b1 are the same as the diameters of the second circumcircles of the second cross-sections of the middle portion of the sixth subtype light diffusion particle 1012b1.

In some embodiments, the second cross-section of the sixth subtype light diffusion particle 1012b1 may have a regular shape or an irregular shape, wherein the regular shape includes a circle, an ellipse, a triangle, a quadrilateral, or the like.

In some embodiments, the sixth subtype light diffusion particle 1012b1 is a cubic particle or cuboid-like particle, the second cross-section of the sixth subtype light diffusion particle 1012b1 is square or rectangular, and the diameter of the second circumcircle of any second cross-sections of the sixth subtype light diffusion particles 1012b1 is the diagonal length of the square or rectangle.

The sixth subtype light diffusion particle 1012b1 is similar to the first subtype light diffusion particle 1012a1, except that the ratio of the length of the major axis of the sixth subtype light diffusion particle to the diameter of the greatest second circumcircle of the second sections of the sixth subtype light diffusion particle is more preferably close to 1, and may be, for example, 1.1, 1.2, 1.3, 1.4, 1.5, 1.6, 1.7, 1.8, 1.9, 2, 2.2, 2.5, 3, or the like.

Referring to FIG. 8f, the first end portion of the seventh subtype light diffusion particle 1012b2 is connected to the second end portion of the seventh subtype light diffusion particle 1012b2, the diameters of the second circumcircles of the second cross-sections at the first end portion of the seventh subtype light diffusion particle 1012b2 gradually decrease in a direction away from the second end portion of the seventh subtype light diffusion particle 1012b2, and the diameters of the second circumcircles of the second sections at the second end portion of the seventh subtype light diffusion particle 1012b2 gradually decrease in a direction away from the first end portion of the seventh subtype light diffusion particle 1012b2.

It should be understood that the diameters of the second circumcircles of the second cross-sections at the first end portion of the seventh subtype light diffusion particle 1012b2 decrease gradually in a direction away from the second end portion of the seventh subtype light diffusion particle 1012b2, indicating that the diameters of the second circumcircles of the second cross-sections at the first end portion of the seventh subtype light diffusion particle have a tendency to decrease in a direction away from the second end portion of the seventh subtype light diffusion particle 1012b2, wherein the tendency includes but not limited to, the diameters of the second circumcircles of the second cross-sections at the first end portion of the seventh subtype light diffusion particles 1012b2 sequentially decreasing in a direction away from the second end portion of the seventh subtype light diffusion particle 1012b2.

It should be understood that the diameters of the second circumcircles of the second cross-sections at the second end of the seventh subtype light diffusion particle 1012b2 decrease gradually in a direction away from the first end portion of the seventh subtype light diffusion particle, indicating that the diameters of the second circumcircles of the second cross-sections at the second end portion of the seventh subtype light diffusion particle 1012b2 have a tendency to decrease in a direction away from the first end portion of the seventh subtype light diffusion particle 1012b2, wherein the tendency includes but not limited to, the diameters of the second circumcircles of the second cross-sections at the second end portion of the seventh subtype light diffusion particle 1012b2 sequentially decreasing in a direction away from the first end portion of the seventh subtype light diffusion particle 1012b2.

In some embodiments, the second cross-section of the seventh subtype light diffusion particle 1012b2 may have a regular shape or an irregular shape, wherein the regular shape may be a circle, an ellipse, a triangle, a quadrilateral, or the like.

In some embodiments, the seventh subtype light diffusion particles 1012b2 are spherical particles or ellipsoidal particles, and the second cross-sections of the seventh subtype light diffusion particle 1012b2 are circular or ellipsoidal. In a case that the second cross-sections of the seventh subtype light diffusion particle 1012b2 are elliptical, the ratio of the major axis of any elliptical second cross-section of the seventh subtype light diffusion particle 1012b2 to the minor axis of the elliptical second cross-section is greater than 1 and less than or equal to 3, and may be, for example, 1.2, 1.5, 1.8, 2, 2.2, 2.5, 2.8, or the like. In a case that the seventh subtype light diffusion particles 1012b2 are spherical particles, any second cross-section of the seventh subtype light diffusion particle is circular and a second circumcircle of any second cross-section coincides with the 1012b2 second cross-section, and a ratio of the length of the major axis of the seventh subtype light diffusion particle 1012b2 to the diameter of the greatest second circumcircle is 1.

The seventh subtype light diffusion particle 1012b2 is similar to the fifth subtype light diffusion particle 1012a5, except that the ratio of the length of the major axis of the seventh subtype light diffusion particle 1012b2 to the diameter of the greatest second circumcircle is less than the ratio of the length of the major axis of the fifth subtype light diffusion particles 1012b2 to the diameter of the greatest first circumcircle. In a case that the seventh subtype light diffusion particles 1012b2 are ellipsoidal particles, the shape of the seventh subtype light diffusion particle 1012b2 is more preferably similar to spherical, that is, the length of the major axis of the seventh subtype light diffusion particle 1012b2 is closer to the diameter of the seventh subtype light diffusion particle 1012b2. Preferably, the ratio of the length of the major axis of the seventh subtype light diffusion particle 1012b2 to the diameter of the greatest second circumcircle is greater than or equal to 1, and less than or equal to 3. More preferably, the ratio of the length of the major axis of the seventh subtype light diffusion particle 1012b2 to the diameter of the greatest second circumcircle is greater than or equal to 1, and less than or equal to 1.5.

Referring to FIG. 8c, the variation value of the diameters of the second circumcircles of the second cross-sections at the middle portion of the eighth subtype light diffusion particles 1012b3 is less than or equal to 1 μm, for example, may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48 μm, 0.45 μm, 0.42 μm, 0.4 μm, 0.38 μm, 0.35 μm, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the direction of the major axis of the eighth subtype light diffusion particle. The diameters of the second circumcircles of the second cross-sections at the first end portion of the eighth subtype light diffusion particles 1012b3 gradually decrease in a direction away from the middle portion of the eighth subtype light diffusion particle 1012b3, and the second end portion of the eighth subtype light diffusion particle 1012b3 having a variation value in diameter less than or equal to 1 μm, for example, the variation value may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48 μm, 0.45 μm, 0.42 μm, 0.4 μm, 0.38 μm, 0.35 μm, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like. In some embodiments, the diameters of the second circumcircles of the second sections at the first end portion of the eighth subtype light diffusion particle 1012b3 gradually decrease in a direction away from the middle portion of the eighth subtype light diffusion particle 1012b3, and the diameters of the second circumcircles of the second sections at the second end portion of the eighth subtype light diffusion particle 1012b3 are the same as the diameters of the second circumcircles of the second sections at the middle portion of the eighth subtype light diffusion particle 1012b3.

It should be understood that the diameters of the second circumcircles of the second cross-sections at the first end portion of the eighth subtype light diffusion particles 1012b3 decrease gradually in a direction away from the middle portion of the eighth subtype light diffusion particle 1012b3, indicating that of the diameters of the second circumcircles of the second cross-sections at the first end portion of the eighth subtype light diffusion particle 1012b3 having a tendency to decrease in a direction away from the middle portion of the eighth subtype light diffusion particle 1012b3, including but not limited to, the diameters of the second circumcircles of the second cross-sections at the first end portion of the eighth subtype light diffusion particle 1012b3 decrease subsequently.

In some embodiments, the second cross-section of the eighth subtype of light diffusion particles 1012b3 may be a regular shape or an irregular shape, wherein the regular shape may be a circle, an ellipse, a triangle, a quadrilateral, or the like.

In some embodiments, the eighth subtype light diffusion particles 1012b3 may be acicular particles, and each of the acicular particles has diameters reduced from middle to end.

In some embodiments, in a case that the eighth subtype light diffusion particle 1012b3 is acicular particle having diameters reduced from an end to another, the second cross-section of the eighth subtype light diffusion particle 1012b3 may be circular or elliptical. In a case that the second cross-section of the second end portion of the eighth subtype light diffusion particle 1012b3 or the second cross-section of the middle portion of the eighth subtype light diffusion particle 1012b3 is elliptical, the ratio of the long axis of any elliptical second cross-section at the second end portion or the middle portion of the eighth subtype light diffusion particle 1012b3 to the minor axis of the elliptical second cross-section is greater than 1 and less than or equal to 3, for example, the ratio may be 1.2, 1.5, 1.8, 2, 2.2, 2.5, 2.8, and the like. The shapes of the second cross-sections at the first end portion of the eighth subtype light diffusion particle 1012b3 coincide with the shapes of the second cross-sections at the middle portion of the eighth subtype light diffusion particle 1012b3, and the areas of the second cross-sections gradually decrease in a direction away from the middle portion of the eighth subtype light diffusion particle 1012b3.

As shown in FIG. 8d, a variation value of the diameters of the second circumcircles of the second cross-sections at the middle portion of the ninth subtype light diffusion particles 1012b4 is less than or equal to 1 μm, for example, may be 0 μm, 0.95 μm, 0.8 μm, 0.78 μm, 0.75 μm, 0.72 μm, 0.7 μm, 0.68 μm, 0.65 μm, 0.62 μm, 0.6 μm, 0.58 μm, 0.55 μm, 0.52 μm, 0.5 μm, 0.48 μm, 0.45 μm, 0.42 μm, 0.4 μm, 0.38 μm, 0.35 μm, 0.32 μm, 0.3 μm, 0.28 μm, 0.25 μm, 0.22 μm, 0.2 μm, 0.18 μm, 0.15 μm, 0.12 μm, 0.1 μm, 0.08 μm, 0.05 μm, 0.02 μm, and the like, along the direction of the major axis of the ninth subtype light diffusion particle 1012b4. The diameters of the second circumcircles of the second cross-sections at the first end portion of the ninth subtype light diffusion particle 1012b4 gradually decrease, and the diameters of the second circumcircles of the second cross-sections at the second end portion of the ninth subtype light diffusion particle 101264 gradually decrease, in a direction away from the middle portion of the ninth subtype light diffusion particle 1012b4. In some embodiments, the second circumcircles of the second cross-sections at the middle portion of the ninth subtype light diffusion particle 1012b4 have uniform diameters along the extension direction of the major axis of the ninth subtype light diffusion particle 1012b4, and the diameters of the second circumcircles of the second cross-sections at the first end portion and second end portion of the ninth subtype light diffusion particle 1012b4 gradually change.

It should be understood that the diameters of the second circumcircles of the second cross-sections of the first end portion of the ninth subtype light diffusion particle 1012b4 decrease gradually in a direction away from the middle portion of the ninth subtype light diffusion particle 1012b4, indicating that the diameters of the second circumcircles of the second cross-sections at the first end portion of the ninth subtype light diffusion particle 1012b4 have a tendency to decrease in a direction away from the middle portion of the ninth subtype light diffusion particle 1012b4, wherein the tendency includes but not limited to, the diameters of the second circumcircles of the second cross-sections at the first end portion of the ninth subtype light diffusion particle 1012b4 decreasing in sequence in a direction away from the middle portion of the ninth subtype light diffusion particle 1012b4.

It should be understood that the diameters of the second circumcircles of the second cross-sections at the second end portion of the ninth subtype light diffusion particle decrease 1012b4 gradually in a direction away from the middle portion of the ninth subtype light diffusion particle, indicating that the diameters of the second circumcircles of the second cross-sections at the second end portion of the ninth subtype light diffusion particle 1012b4 have a tendency to decrease in a direction away from the middle portion of the ninth subtype light diffusion particle 1012b4, wherein the tendency includes but not limited to, the diameters of the second circumcircles of the second cross-sections at the second end portion of the ninth subtype light diffusion particle 1012b4 decreasing in sequence in a direction away from the middle portion of the ninth subtype light diffusion particle 1012b4.

In some embodiments, the first cross-section of the ninth subtype light diffusion particle 1012b4 may be a regular shape or an irregular shape, wherein the regular shape may be a circle, an ellipse, a triangle, a quadrilateral, or the like.

In some embodiments, the ninth subtype light diffusion particles 1012b4 may be acicular particles, and each of the acicular particles has diameters reduced from middle to end.

In some embodiments, in a case that the ninth subtype light diffusion particle 1012b4 is an acicular particle having diameters reduced from middle to end, the second cross-sections of the ninth subtype light diffusion particles 1012b4 may be circular or elliptical. In a case that the second cross-sections at the middle portion of the ninth subtype light diffusion particle 1012b4 are elliptical, a ration of the major axis and the minor axis of any elliptical second cross-section at the middle portion of the ninth subtype light diffusion particle 1012b4 is greater than 1 and less than or equal to 3, for example, may be 1.2, 1.5, 1.8, 2, 2.2, 2.5, 2.8, and the like. The shapes of the second cross-sections at the first end portion and the second end portion of the ninth subtype light diffusion particle 1012b4 coincide with the shapes of the second cross-sections at the middle portion of the ninth subtype light diffusion particle 1012b4, and the areas of the second cross-sections gradually decrease in a direction away from the middle portion of the ninth subtype light diffusion particle 1012b4.

As shown in FIG. 8e, the first end portion of the tenth subtype light diffusion particle 101265 is connected to the second end portion of the tenth subtype light diffusion particle 101265, and the diameters of the second circumcircles of the second cross-sections of the tenth subtype light diffusion particle 1012b5 gradually decrease in a direction from the first end portion of the tenth subtype light diffusion particle 1012b5 to the second end portion of the tenth subtype light diffusion particle 1012b5.

It should be understood that the diameters of the second circumcircles of the second cross-sections of the tenth subtype light diffusion particle 1012b5 decrease gradually in the direction at the first end portion of the tenth subtype light diffusion particle 101265 toward the second end portion, indicating that the diameters of the second circumcircles of the second cross-sections of the tenth subtype light diffusion particle 101265 have a tendency to decrease in the direction of the first end portion of the tenth subtype light diffusion particle 101265 toward the second end portion, wherein the tendency includes but not limited to, the diameters of the second circumcircles of the second cross-sections of the tenth subtype light diffusion particle 1012b5 sequentially decreasing in a direction of the first end portion of the tenth subtype light diffusion particle 1012b5 toward the second end portion.

In some embodiments, the second cross-sections of the tenth subtype light diffusion particle 1012b5 may have a regular shape or an irregular shape, wherein the regular shape may be a circle, an ellipse, a triangle, a quadrilateral, or the like.

In some embodiments, the tenth subtype light diffusion particles 1012b5 may be long cone-shaped particles.

In some embodiments, in a case that the tenth subtype light diffusion particles 101265 are long cone-shaped particles, the second cross-sections of the tenth subtype light diffusion particle 1012b5 may be circular or elliptical. In the direction of the first end portion of the tenth subtype light diffusion particle 101265 toward the second end portion of the tenth subtype light diffusion particle 101265, the second cross-sections of the tenth subtype light diffusion particle 1012b5 conform in shape and gradually decrease in area. In a case that the second cross-sections of the tenth subtype light diffusion particle 101265 are elliptical, the ratio of the major axis of any elliptical second cross-section of the tenth subtype light diffusion particle 1012b5 to the minor axis of the elliptical second cross-section is greater than 1 and less than or equal to 3, for example, may be 1.2, 1.5, 1.8, 2, 2.2, 2.5, 2.8, or the like.

In some embodiments, the second light diffusion particle 1012b has a major axis length greater than or equal to 12 nm, and less than or equal to 12.4 μm, for example, may be 20 nm, 50 nm, 100 nm, 500 nm, 1 μm, 3 μm, 5 μm, 8 μm, 10 μm, and the like, to facilitate dispersion of lights. Preferably, the major axis length of the second light diffusion particle 1012b is greater than or equal to 1 μm and less than or equal to 5 μm. More preferably, the major axis length of the second light diffusion particle 1012b is greater than or equal to 1.5 μm, and less than or equal to 4 μm.

The second light diffusion particles 1012b have a slightly weaker effect on improving the chromaticity viewing angle and the contrast than the first light diffusion particles 1012a, and a significant effect on adjusting the haze of the light diffusion film 101 can be provided with less second-type light diffusion particles 1012b. Thus, the mass fraction of the second light diffusion particles 1012b in the light diffusion particles 1012 may be less than or equal to the mass fraction of the first light diffusion particles 1012a in the light diffusion particles 1012. For example, the mass fraction of the first light diffusion particles 1012a in the light diffusion particles 1012 is greater than or equal to 50%, and the mass fraction of the second light diffusion particles 1012b in the light diffusion particles 1012 is less than or equal to 50%. The mass fraction of the first light diffusion particles 1012a in the light diffusion particles 1012 may be 55%, 60%, 65%, 70%, 75%, 80%, 85%, 90%, 95%, 99%, and the like.

In some embodiments, in a case that the light diffusion particles 1012 include the second light diffusion particles 1012b, and the second light diffusion particles 1012b includes the sixth subtype light diffusion particles and the seventh subtype light diffusion particles, the mass fraction of the sixth subtype light diffusion particles in the light diffusion particles 1012 is less than the mass fraction of the seventh subtype light diffusion particles in the light diffusion particles 1012.

In some embodiments, the first light diffusion particles 1012a include at least the fifth subtype light diffusion particles, the mass fraction of the fifth subtype light diffusion particles in the light diffusion particles 1012 is greater than or equal to 20%, and the mass fraction of the fifth subtype light diffusion particles in the light diffusion particles 1012 is less than or equal to 100%. Preferably, the mass fraction of the fifth subtype of light diffusion particles in the light diffusion particles 1012 is greater than 55%, and the mass fraction of the fifth subtype of light diffusion particles in the light diffusion particles 1012 is less than or equal to 100%, for example, may be 60%, 65%, 70%, 80%, 85%, 90%, 95%, and the like. The first light diffusion particles 1012a further includes the first subtype light diffusion particles, the second subtype light diffusion particles, the third subtype light diffusion particles, and the fourth subtype light diffusion particles. In a case that the second light diffusion particle 1012b further includes the sixth subtype light diffusion particles and/or the seventh subtype light diffusion particles, the sum of mass fractions of the first subtype light diffusion particles, the second subtype light diffusion particles, the third subtype light diffusion particles, the fourth subtype light diffusion particles, and the second light diffusion particles 1012b in the light diffusion particles 1012 is greater than or equal to 80% and less than 100%. Preferably, the sum of the mass fractions of the first subtype light diffusion particles, the second subtype light diffusion particles, the third subtype light diffusion particles, the fourth subtype light diffusion particles, and the second light diffusion particles 1012b in the light diffusion particles 1012 is greater than 0%, and less than 45%, for example, may be 40%, 35%, 30%, 25%, 20%, 15%, 10%, 5%, or the like.

In some embodiments, the mass fraction of the light diffusion particles 1012 in the light diffusion film 101 is less than 3%, for example, may be 0.0001%, 0.001%, 0.01%, 0.02%, 0.05%, 0.1%, 0.5%, 1%, 1.5%, 2%, 2.5%, or the like, as such, the light diffusion particles 1012 can be uniformly dispersed in the light diffusion film 101, and the viewing angle of the polarizer may be promoted by refraction of lights by the light diffusion particles 1012. Thus, there is no need to provide an additional film layer to the polarizer, and the decrease of the emitted lights is avoided, thereby increasing the outgoing lights of the display device while improving the chromaticity viewing angle and the contrast of the display device. The light diffusion particles 1012 have a less mass fraction in the light diffusion film 101 to effectively enhance the contrast and chromaticity viewing angle. Preferably, the mass fraction of the light diffusion particles 1012 in the light diffusion film 101 is greater than or equal to 0.001%, and the mass fraction of the light diffusion particles 1012 in the light diffusion film 101 is less than 3%. More preferably, the mass fraction of the light diffusion particles 1012 in the light diffusion film 101 is greater than or equal to 0.1%, and the mass fraction of the light diffusion particles 1012 in the light diffusion film 101 is less than or equal to 1%. Further preferably, the mass fraction of the light diffusion particles 1012 in the light diffusion film 101 is greater than or equal to 0.1%, and the mass fraction of the light diffusion particles 1012 in the light diffusion film 101 is less than or equal to 0.5%.

In some embodiments, the particle size distribution of the light diffusion particles 1012 may be polydisperse or monodisperse. Preferably, the particle size distribution of the light diffusion particles 1012 is monodisperse, to improve the optical performance of the optical film. In a case that the particle size distribution of the light diffusion particles 1012 is monodisperse, the light diffusion particles 1012 have an average particle size, and the average particle size of the light diffusion particles 1012 is an average value of the lengths of the major axes of the light diffusion particles 1012. In a case that the light diffusion particles 1012 have spherical particles and/or cubic particles, the particle size of the spherical particle is the diameter thereof, and the particle size of the cubic particle is a side length thereof. In a case that the particle size distribution of the light diffusion particles 1012 is monodisperse, the length of the major axis of any light diffusion particle is greater than or equal to 20% of the average particle size of the light diffusion particles, and the length of the major axis of any light diffusion particle is less than or equal to 180% of the average particle size of the light diffusion particles, that is, 20%×the average particle size of the light diffusion particles 10125 the length of the major axis of any light diffusion particle 1012≤180%×the average particle size of the light diffusion particles 1012. Preferably, in a case that the particle size distribution of the light diffusion particles 1012 is monodisperse, the length of the major axis of any light diffusion particle is greater than or equal to 50% of the average particle size of the light diffusion particles, and the length of the major axis of any light diffusion particle is less than or equal to 150% of the average particle size of the light diffusion particles, that is, 50%×the average particle size of the light diffusion particles 1012≤the length of the major axis of any light diffusion particle 1012≤150%×the average particle size of the light diffusion particles 1012.

In some embodiments, the second light diffusion particles 1012b are whiskers. The material of the first light diffusion particles 1012a and the material of the second light diffusion particles 1012b are selected from at least one of organic materials, inorganic materials, and composite materials. For example, the material of the first light diffusion particles 1012a and the material of the second light diffusion particles 1012b may be selected from at least one of polysiloxane, polymethyl methacrylate, polystyrene, silica, titania, zirconia, silicon carbide, silicon nitride, zinc oxide, magnesium oxide, aluminum oxide, calcium sulfate, calcium carbonate, potassium titanate, aluminum borate.

In some embodiments, the second light diffusion particles 1012b and/or the first light diffusion particles 1012a may be surface-modified to facilitate dispersion of the second light diffusion particles 1012b and/or the first light diffusion particles 1012a in the substrate 1011, or to enhance functionality such as toughness of the second light diffusion particles 1012b and/or the first light diffusion particles 1012a. In a case that the second light diffusion particles 1012b and/or the first light diffusion particles 1012a are surface modified, the surfaces of the second light diffusion particles 1012b and/or the first light diffusion particles 1012a are modified by at least one of an inorganic cation, an inorganic anion, a polymer, a coupling agent, or a surfactant. That is, the surfaces of the second light diffusion particles 1012b and/or the first light diffusion particles 1012a includes at least one of an inorganic cation group, an inorganic anion group, a polymer group, a coupling agent group, or a surfactant group.

Specifically, the surfaces of the second light diffusion particles 1012b and/or the first light diffusion particles 1012a are modified with at least one of magnesium chloride, calcium chloride, barium chloride, strontium chloride, stearic acid, sodium stearate, zinc octadecanoate, sulfonic surfactants, thio surfactants, titanates, aluminates, polyacrylamides, silanes, alkyl phosphates, aryl phosphates, alkyl phosphates, aryl phosphates, alkyl alcohol amide phosphates, alkyl alcohol amide phosphates, imidazoline phosphates, imidazoline phosphates, high polyphosphates, high polyphosphates, and siloxane phosphates. Preferably, the surfaces of the second light diffusion particles 1012b and/or the first light diffusion particles 1012a are modified by at least one of a sulfonic surfactant or a thio surfactant. The sulfonic acid-based surfactant may be selected from at least one of alkyl sulfonates, fluoroalkyl sulfonates, and specifically, at least one of sodium dodecyl sulfonate, sodium dodecyl benzene sulfonate, and sodium fluorododecyl sulfonate. The thio-based surfactant may be selected from at least one of a thiol, a fluorothiol, specifically, at least one of an octadecanethiol, a dodecanethiol, a tetradecanethiol, an octadecanethiol, a fluorooctadecanethiol, and a fluorododecanethiol. In a case that the sulfonic acid-based surfactant is mixed with the light diffusion particles 1012 to be surface-modified, the sulfonic acid-based surface-active group forms a sulfonic acid-based shell layer, such as a benzene ring sulfonic acid-based shell layer, on the surface of the whisker, which helps to protect the light diffusion particles 1012, enhance the toughness of the light diffusion particles 1012, and reduce the breakage of the second light diffusion particles 1012b and/or the first light diffusion particles 1012a in the light diffusion film 101. In a case that the thio-type surface-active group is mixed with the light diffusion particles 1012 to be surface-modified, the thio-type surface-active group forms a cross-linked network of O—S—O with hydroxyl groups on the surface of the whisker, and the bond energy of the O—S—O is relatively greater, thereby facilitating the protection of the second light diffusion particles 1012b and/or the first light diffusion particles 1012a during the mixing of the second light diffusion particles 1012b and/or the first light diffusion particles 1012a with the material of the substrate 1011 to form the light diffusion film 101, thereby reducing the breakage of the second light diffusion particles 1012b and/or the first light diffusion particles 1012a, and improving the enhancement effect of optical functions such as contrast and brightness of the second light diffusion particles 1012b and/or the first light diffusion particles 1012a. More preferably, at least one of the second light diffusion particles 1012b and/or the first light diffusion particles 1012a are processed through a fluorine-substituent-containing sulfonic acid-based surfactant, a fluorine-substituent-containing thio-based surfactant, specifically, at least one of sodium fluorododecyl sulfonate, fluoroctylthiol, and fluordodecylthiol. The fluorine atom has high stability in the alkyl chain, the bond energy of the carbon-fluorine bond is higher than the bond energy of the carbon-carbon bond, and the carbon-fluorine bond has a shielding effect on the carbon-carbon bond, thereby facilitating protection of the carbon-carbon bond, enhancing the stability of the second light diffusion particles 1012b and/or the first light diffusion particles 1012a.

In some embodiments, the substrate 1011 is selected from at least one of self-modified or modified polyester, modified or unmodified cellulose acetate.

In some embodiments, the modified or unmodified polyester can include at least one of modified or unmodified polyethylene terephthalate, modified or unmodified polycarbonate, modified or unmodified polymethyl methacrylate, modified or unmodified polyethylene naphthalate. Modified or unmodified cellulose acetate may include modified or unmodified cellulose triacetate.

In some embodiments, the substrate 1011 may include a first sub-substrate and/or a second sub-substrate. The first sub-substrate may be selected from at least one of unmodified polyester, unmodified cellulose acetate. The second sub-substrate may be selected from at least one of a modified polyester, a modified cellulose acetate. In the substrate 1011, the mass fraction of the first sub-substrate is greater than the mass fraction of the second sub-substrate.

In some embodiments, the first sub-substrate and the second sub-substrate are uniformly mixed with each other, and the mass fraction of the first sub-substrate in the substrate 1011 is greater than or equal to 65%, for example, may be 70%, 75%, 80%, 85%, 90%, 95%, 99%, and the like. The mass fraction of the second sub-substrate in the substrate 1011 is less than or equal to 35%, for example, may be 1%, 5%, 10%, 15%, 20%, 25%, 30%, etc. As such, the modified polyester such as polyethylene terephthalate, and the unmodified polyester such as polyethylene terephthalate have good miscibility with each other; or the non-modified cellulose acetate such as cellulose triacetate, and the unmodified cellulose acetate such as cellulose triacetate have good miscibility. Thus, the mechanical property, flatness, crystallinity of the substrate 1011 can be improved, and the dispersibility of the light diffusion particles 1012 can be improved, thereby improving the optical property of the light diffusion film 101.

In some embodiments, the modified cellulose triacetate, modified polyethylene terephthalate, modified polycarbonate, modified polymethacrylate, or modified polyethylene naphthalate can be obtained by hydrophilic or lipophilic modification of unmodified triacetate fibers, unmodified polyethylene terephthalate, unmodified polycarbonate, unmodified polymethacrylate, or unmodified polyethylene naphthalate, respectively. For example, the modified polyethylene terephthalate may be obtained by introducing a linear alkyl side chain, a carboxyl side chain, a hydroxyl side chain, or a side chain of a fluorine-containing group to the unmodified polyethylene terephthalate. In a case that the modified polyethylene terephthalate is obtained by introducing a carboxyl side chain and/or a hydroxyl side chain to the unmodified polyethylene terephthalate, a group

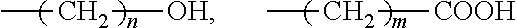

can introduced into the phenyl group of the unmodified polyethylene terephthalate, wherein n and m are both integers greater than or equal to 0 and less than or equal to 10.

In some embodiments, in a case that the first sub-substrate is selected from the unmodified polyethylene terephthalate, and the second sub-substrate is selected from the modified polyethylene terephthalate, the mass fraction of the second sub-substrate in the substrate 1011 is less than or equal to 35%, which provides a good compatibility of the modified polyethylene terephthalate with the unmodified polyethylene terephthalate, helps to improve the mechanical, flatness, crystallinity of the substrate 1011 and the dispersion of the light diffusion particles 1012, thereby improving the optical properties of the light diffusion film 101.

In some embodiments, the difference in refractive index between the substrate 1011 and the light diffusion particles 1012 is greater than or equal to 0.02, for example, may be 0.03, 0.05, 0.09, 0.1, 0.15, 0.2, and the like, to achieve the light diffusion function of the light diffusion particles 1012. Preferably, the difference in refractive index between the substrate 1011 and that of the light diffusion particles 1012 is greater than or equal to 0.1, for example, may be 0.12, 0.13, 0.14, 0.15, 0.2, or the like.

In some embodiments, in the light diffusion particles 1012 in the same light diffusion film 101, the material of the first light diffusion particles 1012a and the material of the second light diffusion particles 1012b may be the same or different, and therefore, the difference in refractive index between the first light diffusion particles 1012a and the substrate 1011, and the difference in refractive index between the second light diffusion particles 1012b and the substrate 1011 may be the same or different.

In some embodiments, the refractive index of the first light diffusion particles 1012a is greater than the refractive index of the substrate 1011. The refractive index of the second light diffusion particles 1012b is greater than the refractive index of the substrate 1011. The refractive index of the second light diffusion particles 1012b is greater than the refractive index of the first light diffusion particles 1012a.

In some embodiments, the substrate 1011 has a glass transition temperature of 70° C. to 600° C., for example, the temperature may be 80° C., 90° C., 100° C., 150° C., 200° C., 250° C., 300° C., 350° C., 400° C., 450° C., 500° C., 550° C., and the like.

In some embodiments, the substrate 1011 has an elastic modulus of 500 MPa to 5000 MPa at 23° C., for example, the elastic modulus may be 600 MPa, 700 MPa, 800 MPa, 900 MPa, 1000 MPa, 1200 MPa, 1500 MPa, 1800 MPa, 2000 MPa, 2200 MPa, 2500 MPa, 2800 MPa, 3000 MPa, 3200 MPa, 3500 MPa, 3800 MPa, 4000 MPa, 4200 MPa, 4500 MPa, 4800 MPa, and the like.

In some embodiments, the elastic modulus of the substrate 1011 may be obtained in a humidity of 50%.

In some embodiments, the thickness of the light diffusion film 101 is greater than or equal to 5 μm, and the thickness of the light diffusion film 101 is less than or equal to 500 μm, for example, the thickness may be 10 μm, 50 μm, 60 μm, 100 μm, 150 μm, 200 μm, 250 μm, 300 μm, 350 μm, 400 μm, 450 μm, and, in order to facilitate processing of the light diffusion film 101 and to maintain appropriate light transmittance of the light diffusion film 101. Preferably, the thickness of the light diffusion film 101 is greater than or equal to 15 μm, and the thickness of the light diffusion film 101 is less than or equal to 150 μm, for example, the thickness may be 20 μm, 25 μm, 30 μm, 40 μm, 50 μm, 60 μm, 80 μm, 100 μm, 120 μm, 130 μm, 140 μm, or the like.

According to the light diffusion film 101 according to the embodiment of the present application, by adding the light diffusion particles 1012 having a mass fraction less than 3% to the substrate 1011 of the light diffusion film 101, it is possible to increase the viewing angle of the polarizer by refraction of the lights by the light diffusion particles 1012. Thus, there is no need to provide an additional film layer to the polarizer, and the decrease of the emitted lights is avoided, thereby increasing the outgoing lights of the display device while improving the chromaticity viewing angle and the contrast of the display device.

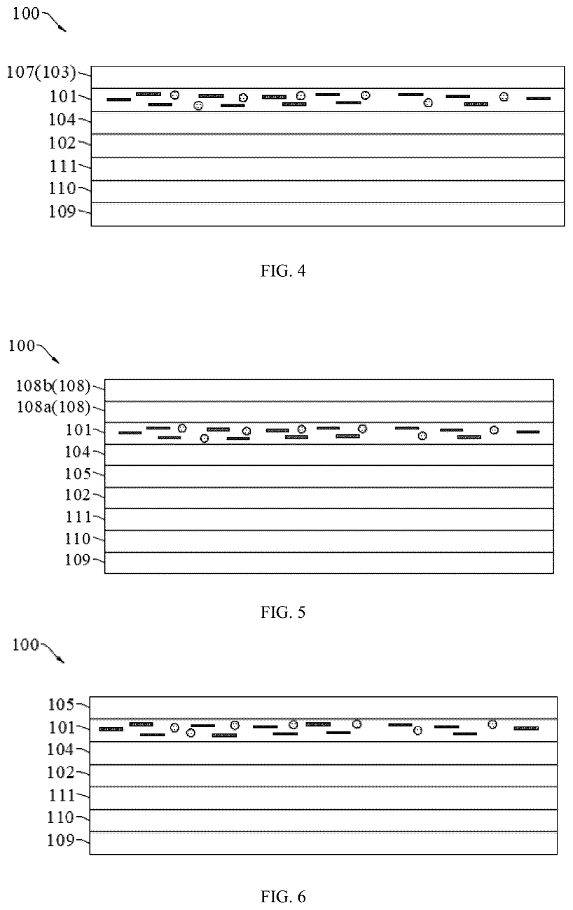

Referring to FIGS. 3 to 6, an embodiment of the present application further provides a polarizer 100 including a light diffusion film 101 as described above.

The polarizing plate 100 further includes a polarizing layer 102 on a side of the light diffusion film 101.

Referring to FIGS. 3 to 6, in some embodiments, the polarizer 100 further includes an optically functional layer 103 on at least one side of the substrate 1011.

The optical functional layer 103 is disposed between the polarizing layer 102 and the light diffusion film 101. Alternatively, the optical functional layer 103 is disposed on the side of the light diffusion film 101away from the polarizing layer 102.

In some embodiments, the optical functional layer 103 is disposed on the side of the light diffusion film 101 away from the polarizing layer 102, and the polarizer 100 further includes a first adhesive layer 104 disposed on a side of the light diffusion film 101 close to the polarizing layer 102.

The first adhesive layer 104 is in direct contact with the polarizing layer 102; alternatively, the polarizer 100 further includes a protective layer 105 between the light diffusion film 101 and the polarizing layer 102, and the first adhesive layer 104 is in direct contact with the protective layer 105.

In some embodiments, the first adhesive layer 104 is in direct contact with the light diffusion film 101 and the first adhesive layer 104 is in direct contact with the polarizing layer 102. Alternatively, the first adhesive layer 104 is in direct contact with the light diffusion film 101, and the first adhesive layer 104 is in direct contact with the protective layer 105.

In some embodiments, the first adhesive layer 104 may be selected from at least one of a water adhesive, a pressure sensitive adhesive, and an ultraviolet adhesive, the material of the water adhesive may be selected from polyvinyl alcohol, the material of the pressure sensitive adhesive may be selected from acrylate copolymers, and the material of the ultraviolet adhesive may be selected from multifunctional acrylate monomers.

Referring to FIGS. 3 to 5, in some embodiments, the optical functional layer 103 includes at least one of a transparent hardening sublayer 107, a low reflection sublayer 108, an anti-reflection sublayer, an anti-fingerprint sublayer, and an anti-static sublayer. In a case that the optical functional layer 103 is a low reflection sublayer 108, the low reflection sublayer 108 may be formed by stacking a transparent hardened sub-portion 108a and a low refraction sub-portion 108b.

In some embodiments, the polarizing layer 102 includes polyvinyl alcohol and a dye.

In some embodiments, the polarizer 100 further includes a release layer 109 on the side of the polarizing layer 102 away from the light diffusion film 101, the release layer 109 is bonded to the polarizing layer 102 by a second adhesive layer 110. When the polarizer 100 is applied to the display device, the release layer 109 is removed to expose the second adhesive layer 110 so that the polarizer 100 is adhered to the display panel through the second adhesive layer 110.

In some embodiments, the polarizer 100 further includes a compensation layer 111 between the second adhesive layer 110 and the polarizing layer 102.

According to the present embodiment of the present application, the arrangement of the light diffusion film 101 avoids optical defects such as molar lines or white spots caused by the polarizer, and improves the chromaticity viewing angle and contrast of the display device.

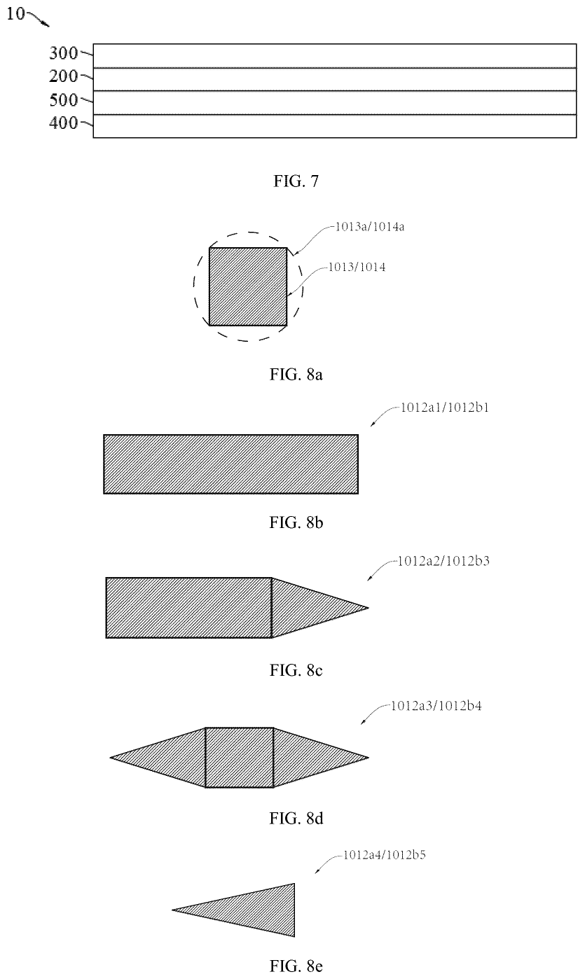

Referring to FIG. 7, an embodiment of the present application further provides a display device 10 including a polarizer 100 as described above.

Specifically, the display device includes a display panel 200 and a first sub-polarizer 300 disposed on the outgoing side of the display panel 200, the first sub-polarizer 300 is selected from the polarizer 100 described above.

In some embodiments, the display panel 200 may be a liquid crystal display panel, a spontaneous display panel, or the like, and the spontaneous display panel may be an organic light-emitting diode (OLED) display panel, or the like.

In some embodiments, the light diffusion film 101 in the first sub-polarizer 300 is disposed on a side of the polarizing layer 102 in the first polarizer 300 away from the display panel.

In a case that the display panel 200 is a liquid crystal display panel, the display device 10 further includes a backlight module 400 on a side of the display panel 200 away from the first polarizer 300, and the backlight module 400 is used to provide a light source for the display panel 200. The display device 10 also includes a second sub-polarizer 500 disposed between the backlight module 400 and the display panel 200. The second sub-polarizer 500 may be selected from the polarizer 100 as described above.

The present application is described following in more detail with reference to some examples. It should be noted, however, that these examples are provided for purposes of illustration only and should not be construed as limiting the application in any way.

### Example 1

In this example, the material of the substrate is unmodified polyethylene terephthalate, and the light diffusion particles in the substrate are mixed with the spherical silica and the rod silica in a mass ratio of 1:1 to form the light diffusion film 1. The mass fraction of the light diffusion particles in the light diffusion film 1 is 0.1%.

### Example 2

This example is the same as or similar to Example 1, except that the light diffusion particles in the substrate are ellipsoidal silica and rod silica mixed at a mass ratio of 1:1 to form the light diffusion film 2, and the mass fraction of the light diffusion particles in the light diffusion film 2 is 0.5%.

### Comparative Example 1

This comparative example is similar to Example 2, except that the mass fraction of light diffusion particles in the light diffusion film of the comparative example is 5%.

The light diffusion film 1 from Example 1, the light diffusion film 2 from Example 2, and the comparative light diffusion 1 film from Comparative Example 1 are respectively disposed on the side of the corresponding polarizer away from the display panel, and the corresponding polarizer is respectively attached to the surface of the 75-inch liquid crystal display panel, to perform a test for optical effect, and the results are shown in Table 1. The polarizer to be tested includes a compensation layer, a polarizing layer, a protective layer, a light diffusion film, and a transparent hardened sub-layer, which are sequentially laminated.

Note that haze is measured by the haze measurement instrument NDH7000.

The dark state ratio refers to the ratio of the brightness of the display panel observed in the dark state and with the angle 30° or 60° relative to the center of the display panel to the brightness of the display panel observed in the dark state and in the center of the display panel.

The contrast is the ratio of brightness in the white state to brightness in the dark state of the display panel. In this test, the center brightness of the display panel in the white state and the center brightness of the display panel in the dark state are measured.

The brightness viewing angle is a value of the side viewing angle when the side viewing angle brightness is half of the front viewing angle brightness.

The transmittance is the ratio of the white brightness to the brightness of the backlight module.

The chromaticity viewing angle measurement is a viewing angle measurement performed by the CESI0.03.

TABLE 1

| | | | | | | Brightness | |
|---|---|---|---|---|---|---|---|
| | Chromaticity | | Transmit- | | | viewing | |
| | viewing angle | | tance | Dark ratio | | angle | Haze |
| | (°) | Contrast | (%) | 30° | 60° | (°) | (%) |
| Light diffusion film 1 | 134 | 5335.22 | 5.01 | 3.39 | 3.79 | 75 | 23.03 |
| Light diffusion film 2 | >160 | 4570 | 4.43 | 3.47 | 4.25 | 74 | 66.16 |
| Comparative light | >160 | 2066 | 2.98 | 1.6 | 1.7 | 75 | 95 |
| diffusion film 1 | | | | | | | |

As can be seen from Table 1, in a case that the mass fraction of the light diffusion particles formed by mixing particles of different shapes in the light diffusion film is less than 3%, a greater chromaticity viewing angle can be obtained, and the contrast, light transmittance, and the like are significantly improved compared with the comparative light diffusion film 1 in which the mass fraction of the light diffusion particles in the light diffusion film is greater than 3%.

An embodiment of the present application discloses a light diffusion film including a substrate and light diffusion particles dispersed in the substrate, wherein the mass fraction of the light diffusion particles in the substrate is less than 3%. According to the present application, by adding the light diffusion particles having a mass fraction of less than 3% to the substrate of the light diffusion film, the viewing angle of the polarizer can be improved by refraction of lights by the light diffusion particles. Thus, there is no need to provide an additional film layer to the polarizer, and the decrease of the emitted lights is avoided, thereby increasing the outgoing lights of the display device while improving the chromaticity viewing angle and the contrast of the display device.

The above describes in detail a light diffusion film, a polarizer, and a display device according to an embodiment of the present application, and the principles and embodiments of the present application are described herein using embodiments and examples. The above description of the embodiments and examples is merely intended to assist in understanding the method of the present application and the core idea thereof. At the same time, variations in the detailed description and scope of application will occur to those skilled in the art in accordance with the teachings of the present application, and in light of the foregoing, the present specification is not to be construed as limiting the application.

1. A light diffusion film, comprising:
a substrate; and
light diffusion particles dispersed in the substrate;
wherein a mass fraction of the light diffusion particles in the substrate is less than 3%.

2. The light diffusion film of claim 1, wherein the light diffusion particles comprise first light diffusion particles;
wherein the first light diffusion particles have a plurality of first cross-sections, each of the first cross-sections has a first circumcircle, a ratio of a length of a major axis of the first light diffusion particle to a diameter of a greatest first circumcircle of the first light diffusion particle is greater than or equal to 5, and less than 100, and the first cross-section is perpendicular to an extension direction of the major axis of the first light diffusion particle.

3. The light diffusion film of claim 2, wherein the first light diffusion particles are selected from at least one of a first subtype light diffusion particle, a second subtype light diffusion particle, a third subtype light diffusion particle, a fourth subtype light diffusion particle, and a fifth subtype light diffusion particle having different shapes from each other;
wherein a variation value of diameters of first circumcircles of first cross-sections of the first subtype light diffusion particle is less than or equal to 0.3 μm along an extension direction of a major axis of the first subtype light diffusion particle;
a variation value of diameters of first circumcircles of first cross-sections at a middle portion of the second subtype light diffusion particle is less than or equal to 1 μm along an extension direction of a major axis of the second subtype light diffusion particle; in a direction away from the middle portion of the second subtype light diffusion particle, a variation value of diameters of first circumcircles of first cross-sections at a first end portion of the second subtype light diffusion particle gradually decrease, and a variation value of diameters of first circumcircles of first cross-sections at a second end portion of the second subtype light diffusion particle is less than or equal to 1 μm;
a variation value of diameters of first circumcircles of first cross-sections at a middle portion of the third subtype light diffusion particle is less than or equal to 1 μm along an extension direction of a major axis of the third subtype light diffusion particle; in a direction away from the middle portion of the third subtype light diffusion particle, a variation value of diameters of first circumcircles of first cross-sections at a first end portion of the third subtype light diffusion particle gradually decrease, and a variation value of diameters of first circumcircles of first cross-sections at a second end portion of the third subtype light diffusion particle gradually decrease;
a first end portion of the fourth subtype light diffusion particle is connected to a second end portion of the fourth subtype light diffusion particle, and diameters of first circumcircles of first cross-sections of the fourth subtype light diffusion particle gradually decrease in a direction from the first end portion of the fourth subtype light diffusion particle to the second end portion of the fourth subtype light diffusion particle; and
a first end portion of the fifth subtype light diffusion particle is connected to a second end portion of the fifth subtype light diffusion particle, diameters of first circumcircles of first cross-sections at the first end portion of the fifth subtype light diffusion particle gradually decrease in a direction away from the second end portion of the fifth subtype light diffusion particle, and diameters of first circumcircles of first cross-sections at the second end portion of the fifth subtype light diffusion particle gradually decrease in a direction away from the first end portion of the fifth subtype light diffusion particle.

4. The light diffusion film of claim 3, wherein the light diffusion particles further comprise second light diffusion particles;
wherein the second light diffusion particles have a plurality of second cross-sections, each of the second cross-sections has a second circumcircle, a ratio of a length of a major axis of the second light diffusion particle to a diameter of a greatest second circumcircle is greater than or equal to 1, and less than 5, and the second cross-section is perpendicular to an extension direction of the major axis of the second light diffusion particle.

5. The light diffusion film of claim 4, wherein the second light diffusion particles are selected from at least one of a sixth subtype light diffusion particle, a seventh subtype light diffusion particle, an eighth subtype light diffusion particle, a ninth subtype light diffusion particle, and a tenth subtype light diffusion particle having different shapes from each other;
wherein a variation value of diameters of second circumcircles of second cross-sections of the sixth subtype light diffusion particle is less than or equal to 0.3 μm along an extension direction of a major axis of the sixth subtype light diffusion particle;
a first end portion of the seventh subtype light diffusion particle is connected to a second end portion of the seventh subtype light diffusion particle, diameters of second circumcircles of second sections at the first end portion of the seventh subtype light diffusion particle gradually decrease in a direction away from the second end portion of the seventh subtype light diffusion particle, and diameters of second circumcircles of second cross-sections at the second end portion of the seventh subtype light diffusion particle gradually decrease in a direction away from the first end portion of the seventh subtype light diffusion particle;
a variation value of diameters of second circumcircles of second cross-sections at a middle portion of the eighth subtype light diffusion particle is less than or equal to 1 μm along an extension direction of a major axis of the eighth subtype light diffusion particle; in a direction away from the middle portion of the eighth subtype light diffusion particle, a variation value of diameters of second circumcircles of second cross-sections at a first end portion of the eighth subtype light diffusion particle gradually decrease, and a variation value of diameters of second circumcircles of second cross-sections at a second end portion of the eighth subtype light diffusion particle is less than or equal to 1 μm;
a variation value of diameters of second circumcircles of second cross-sections at a middle portion of the ninth subtype light diffusion particle is less than or equal to 1 μm along an extension direction of a major axis of the ninth subtype light diffusion particle; in a direction away from the middle portion of the ninth subtype light diffusion particle, a variation value of diameters of second circumcircles of second cross-sections at a first end portion of the ninth subtype light diffusion particle gradually decrease, and a variation value of diameters of second circumcircles of second cross-sections at a second end portion of the ninth subtype light diffusion particle gradually decrease; and
a first end portion of the tenth subtype light diffusion particle is connected to a second end portion of the tenth subtype light diffusion particle, and diameters of second circumcircles of second cross-sections of the tenth subtype light diffusion particle gradually decrease in a direction from the first end portion of the tenth subtype light diffusion particle to the second end portion of the tenth subtype light diffusion particle.

6. The light diffusion film of claim 5, wherein the first subtype light diffusion particle is selected from a rod-shaped particle, the second subtype light diffusion particle is selected from an acicular particle having reduced diameters from middle to an end, the third subtype light diffusion particle is selected from an acicular particle having reduced diameters from middle to both ends, the fourth subtype light diffusion particle is selected from a long cone-shaped particle, the fifth subtype light diffusion particle is selected from a bicone-shaped particle and/or an ellipsoid-shaped particle, the sixth subtype light diffusion particle is selected from a cubic particle or a cuboid-shaped particle, the seventh subtype light diffusion particle is selected from a spherical particle or an ellipsoid-shaped particle, the eighth subtype light diffusion particle is selected from an acicular particle having reduced diameters from middle to an end, the ninth subtype light diffusion particle is selected from an acicular particle having reduced diameters from middle to both ends, and the tenth subtype light diffusion particle is selected from a long cone-shaped particle.

7. The light diffusion film of claim 3, wherein a mass fraction of the fifth subtype light diffusion particles in the light diffusion particles is greater than or equal to 20%, and a mass fraction of the fifth subtype light diffusion particles in the light diffusion particles is less than or equal to 100%.

8. The light diffusion film of claim 1, wherein each of the light diffusion particles has an average particle size, a length of ta major axis of the light diffusion particle is greater than or equal to 20% of the average particle size of the light diffusion particle, and the length of the major axis of the light diffusion particle is less than or equal to 180% of the average particle size of the light diffusion particle.

9. The light diffusion film of claim 1, wherein the substrate comprises a first sub-substrate selected from at least one of an unmodified polyester, an unmodified acetate fiber, and/or a second sub-substrate selected from at least one of a modified polyester, a modified cellulose acetate;
wherein a mass fraction of the first sub-substrate in the substrate is greater than or equal to 65%, and the mass fraction of the first sub-substrate in the substrate is less than or equal to 100%; and
a mass fraction of the second sub-substrate in the substrate is greater than or equal to 0%, and the mass fraction of the second sub-substrate in the substrate is less than or equal to 35%.

10. A polarizer, comprising a light diffusion film, wherein the light diffusion film comprises:
a substrate; and
light diffusion particles dispersed in the substrate;
wherein a mass fraction of the light diffusion particles in the substrate is less than 3%.

11. The polarizer of claim 10, wherein the light diffusion particles comprise first light diffusion particles;
wherein the first light diffusion particles have a plurality of first cross-sections, each of the first cross-sections has a first circumcircle, a ratio of a length of a major axis of the first light diffusion particle to a diameter of a greatest first circumcircle of the first light diffusion particle is greater than or equal to 5, and less than 100, and the first cross-section is perpendicular to an extension direction of the major axis of the first light diffusion particle;
wherein the first light diffusion particles are selected from at least one of a first subtype light diffusion particle, a second subtype light diffusion particle, a third subtype light diffusion particle, a fourth subtype light diffusion particle, and a fifth subtype light diffusion particle having different shapes from each other;
a variation value of diameters of first circumcircles of first cross-sections of the first subtype light diffusion particle is less than or equal to 0.3 μm along an extension direction of a major axis of the first subtype light diffusion particle;
a variation value of diameters of first circumcircles of first cross-sections at a middle portion of the second subtype light diffusion particle is less than or equal to 1 μm along an extension direction of a major axis of the second subtype light diffusion particle; in a direction away from the middle portion of the second subtype light diffusion particle, a variation value of diameters of first circumcircles of first cross-sections at a first end portion of the second subtype light diffusion particle gradually decrease, and a variation value of diameters of first circumcircles of first cross-sections at a second end portion of the second subtype light diffusion particle is less than or equal to 1 μm;
a variation value of diameters of first circumcircles of first cross-sections at a middle portion of the third subtype light diffusion particle is less than or equal to 1 μm along an extension direction of a major axis of the third subtype light diffusion particle; in a direction away from the middle portion of the third subtype light diffusion particle, a variation value of diameters of first circumcircles of first cross-sections at a first end portion of the third subtype light diffusion particle gradually decrease, and a variation value of diameters of first circumcircles of first cross-sections at a second end portion of the third subtype light diffusion particle gradually decrease;
a first end portion of the fourth subtype light diffusion particle is connected to a second end portion of the fourth subtype light diffusion particle, and diameters of first circumcircles of first cross-sections of the fourth subtype light diffusion particle gradually decrease in a direction from the first end portion of the fourth subtype light diffusion particle to the second end portion of the fourth subtype light diffusion particle; and
a first end portion of the fifth subtype light diffusion particle is connected to a second end portion of the fifth subtype light diffusion particle, diameters of first circumcircles of first cross-sections at the first end portion of the fifth subtype light diffusion particle gradually decrease in a direction away from the second end portion of the fifth subtype light diffusion particle, and diameters of first circumcircles of first cross-sections at the second end portion of the fifth subtype light diffusion particle gradually decrease in a direction away from the first end portion of the fifth subtype light diffusion particle.

12. The polarizer of claim 11, wherein the light diffusion particles further comprise second light diffusion particles;
wherein the second light diffusion particles have a plurality of second cross-sections, each of the second cross-sections has a second circumcircle, a ratio of a length of a major axis of the second light diffusion particle to a diameter of a greatest second circumcircle is greater than or equal to 1, and less than 5, and the second cross-section is perpendicular to an extension direction of the major axis of the second light diffusion particle;
wherein the second light diffusion particles are selected from at least one of a sixth subtype light diffusion particle, a seventh subtype light diffusion particle, an eighth subtype light diffusion particle, a ninth subtype light diffusion particle, and a tenth subtype light diffusion particle having different shapes from each other;
wherein a variation value of diameters of second circumcircles of second cross-sections of the sixth subtype light diffusion particle is less than or equal to 0.3 μm along an extension direction of a major axis of the sixth subtype light diffusion particle;
a first end portion of the seventh subtype light diffusion particle is connected to a second end portion of the seventh subtype light diffusion particle, diameters of second circumcircles of second sections at the first end portion of the seventh subtype light diffusion particle gradually decrease in a direction away from the second end portion of the seventh subtype light diffusion particle, and diameters of second circumcircles of second cross-sections at the second end portion of the seventh subtype light diffusion particle gradually decrease in a direction away from the first end portion of the seventh subtype light diffusion particle;
a variation value of diameters of second circumcircles of second cross-sections at a middle portion of the eighth subtype light diffusion particle is less than or equal to 1 μm along an extension direction of a major axis of the eighth subtype light diffusion particle; in a direction away from the middle portion of the eighth subtype light diffusion particle, a variation value of diameters of second circumcircles of second cross-sections at a first end portion of the eighth subtype light diffusion particle gradually decrease, and a variation value of diameters of second circumcircles of second cross-sections at a second end portion of the eighth subtype light diffusion particle is less than or equal to 1 μm;
a variation value of diameters of second circumcircles of second cross-sections at a middle portion of the ninth subtype light diffusion particle is less than or equal to 1 μm along an extension direction of a major axis of the ninth subtype light diffusion particle; in a direction away from the middle portion of the ninth subtype light diffusion particle, a variation value of diameters of second circumcircles of second cross-sections at a first end portion of the ninth subtype light diffusion particle gradually decrease, and a variation value of diameters of second circumcircles of second cross-sections at a second end portion of the ninth subtype light diffusion particle gradually decrease; and
a first end portion of the tenth subtype light diffusion particle is connected to a second end portion of the tenth subtype light diffusion particle, and diameters of second circumcircles of second cross-sections of the tenth subtype light diffusion particle gradually decrease in a direction from the first end portion of the tenth subtype light diffusion particle to the second end portion of the tenth subtype light diffusion particle.

13. The polarizer of claim 12, wherein the first subtype light diffusion particle is selected from a rod-shaped particle, the second subtype light diffusion particle is selected from an acicular particle having reduced diameters from middle to an end, the third subtype light diffusion particle is selected from an acicular particle having reduced diameters from middle to both ends, the fourth subtype light diffusion particle is selected from a long cone-shaped particle, the fifth subtype light diffusion particle is selected from a bicone-shaped particle and/or an ellipsoid-shaped particle, the sixth subtype light diffusion particle is selected from a cubic particle or a cuboid-shaped particle, the seventh subtype light diffusion particle is selected from a spherical particle or an ellipsoid-shaped particle, the eighth subtype light diffusion particle is selected from an acicular particle having reduced diameters from middle to an end, the ninth subtype light diffusion particle is selected from an acicular particle having reduced diameters from middle to both ends, and the tenth subtype light diffusion particle is selected from a long cone-shaped particle.

14. The polarizer of claim 11, wherein a mass fraction of the fifth subtype light diffusion particles in the light diffusion particles is greater than or equal to 20%, and a mass fraction of the fifth subtype light diffusion particles in the light diffusion particles is less than or equal to 100%.

15. The polarizer of claim 10, wherein each of the light diffusion particles has an average particle size, a length of ta major axis of the light diffusion particle is greater than or equal to 20% of the average particle size of the light diffusion particle, and the length of the major axis of the light diffusion particle is less than or equal to 180% of the average particle size of the light diffusion particle.

16. The polarizer of claim 10, wherein the substrate comprises a first sub-substrate selected from at least one of an unmodified polyester, an unmodified acetate fiber, and/or a second sub-substrate selected from at least one of a modified polyester, a modified cellulose acetate;
wherein a mass fraction of the first sub-substrate in the substrate is greater than or equal to 65%, and the mass fraction of the first sub-substrate in the substrate is less than or equal to 100%; and
a mass fraction of the second sub-substrate in the substrate is greater than or equal to 0%, and the mass fraction of the second sub-substrate in the substrate is less than or equal to 35%

17. A display device, comprising a polarizer, wherein the polarizer comprises a light diffusion film, and the light diffusion film comprises:
a substrate; and
light diffusion particles dispersed in the substrate;
wherein a mass fraction of the light diffusion particles in the substrate is less than 3%.

18. The display device of claim 17, wherein the light diffusion particles comprise first light diffusion particles;
wherein the first light diffusion particles have a plurality of first cross-sections, each of the first cross-sections has a first circumcircle, a ratio of a length of a major axis of the first light diffusion particle to a diameter of a greatest first circumcircle of the first light diffusion particle is greater than or equal to 5, and less than 100, and the first cross-section is perpendicular to an extension direction of the major axis of the first light diffusion particle;
wherein the first light diffusion particles are selected from at least one of a first subtype light diffusion particle, a second subtype light diffusion particle, a third subtype light diffusion particle, a fourth subtype light diffusion particle, and a fifth subtype light diffusion particle having different shapes from each other;
a variation value of diameters of first circumcircles of first cross-sections of the first subtype light diffusion particle is less than or equal to 0.3 μm along an extension direction of a major axis of the first subtype light diffusion particle;
a variation value of diameters of first circumcircles of first cross-sections at a middle portion of the second subtype light diffusion particle is less than or equal to 1 μm along an extension direction of a major axis of the second subtype light diffusion particle; in a direction away from the middle portion of the second subtype light diffusion particle, a variation value of diameters of first circumcircles of first cross-sections at a first end portion of the second subtype light diffusion particle gradually decrease, and a variation value of diameters of first circumcircles of first cross-sections at a second end portion of the second subtype light diffusion particle is less than or equal to 1 μm;
a variation value of diameters of first circumcircles of first cross-sections at a middle portion of the third subtype light diffusion particle is less than or equal to 1 μm along an extension direction of a major axis of the third subtype light diffusion particle; in a direction away from the middle portion of the third subtype light diffusion particle, a variation value of diameters of first circumcircles of first cross-sections at a first end portion of the third subtype light diffusion particle gradually decrease, and a variation value of diameters of first circumcircles of first cross-sections at a second end portion of the third subtype light diffusion particle gradually decrease;
a first end portion of the fourth subtype light diffusion particle is connected to a second end portion of the fourth subtype light diffusion particle, and diameters of first circumcircles of first cross-sections of the fourth subtype light diffusion particle gradually decrease in a direction from the first end portion of the fourth subtype light diffusion particle to the second end portion of the fourth subtype light diffusion particle; and
a first end portion of the fifth subtype light diffusion particle is connected to a second end portion of the fifth subtype light diffusion particle, diameters of first circumcircles of first cross-sections at the first end portion of the fifth subtype light diffusion particle gradually decrease in a direction away from the second end portion of the fifth subtype light diffusion particle, and diameters of first circumcircles of first cross-sections at the second end portion of the fifth subtype light diffusion particle gradually decrease in a direction away from the first end portion of the fifth subtype light diffusion particle.

19. The display device of claim 18, wherein the light diffusion particles further comprise second light diffusion particles;
wherein the second light diffusion particles have a plurality of second cross-sections, each of the second cross-sections has a second circumcircle, a ratio of a length of a major axis of the second light diffusion particle to a diameter of a greatest second circumcircle is greater than or equal to 1, and less than 5, and the second cross-section is perpendicular to an extension direction of the major axis of the second light diffusion particle;
wherein the second light diffusion particles are selected from at least one of a sixth subtype light diffusion particle, a seventh subtype light diffusion particle, an eighth subtype light diffusion particle, a ninth subtype light diffusion particle, and a tenth subtype light diffusion particle having different shapes from each other;
wherein a variation value of diameters of second circumcircles of second cross-sections of the sixth subtype light diffusion particle is less than or equal to 0.3 μm along an extension direction of a major axis of the sixth subtype light diffusion particle;
a first end portion of the seventh subtype light diffusion particle is connected to a second end portion of the seventh subtype light diffusion particle, diameters of second circumcircles of second sections at the first end portion of the seventh subtype light diffusion particle gradually decrease in a direction away from the second end portion of the seventh subtype light diffusion particle, and diameters of second circumcircles of second cross-sections at the second end portion of the seventh subtype light diffusion particle gradually decrease in a direction away from the first end portion of the seventh subtype light diffusion particle;
a variation value of diameters of second circumcircles of second cross-sections at a middle portion of the eighth subtype light diffusion particle is less than or equal to 1 μm along an extension direction of a major axis of the eighth subtype light diffusion particle; in a direction away from the middle portion of the eighth subtype light diffusion particle, a variation value of diameters of second circumcircles of second cross-sections at a first end portion of the eighth subtype light diffusion particle gradually decrease, and a variation value of diameters of second circumcircles of second cross-sections at a second end portion of the eighth subtype light diffusion particle is less than or equal to 1 μm;
a variation value of diameters of second circumcircles of second cross-sections at a middle portion of the ninth subtype light diffusion particle is less than or equal to 1 μm along an extension direction of a major axis of the ninth subtype light diffusion particle; in a direction away from the middle portion of the ninth subtype light diffusion particle, a variation value of diameters of second circumcircles of second cross-sections at a first end portion of the ninth subtype light diffusion particle gradually decrease, and a variation value of diameters of second circumcircles of second cross-sections at a second end portion of the ninth subtype light diffusion particle gradually decrease; and
a first end portion of the tenth subtype light diffusion particle is connected to a second end portion of the tenth subtype light diffusion particle, and diameters of second circumcircles of second cross-sections of the tenth subtype light diffusion particle gradually decrease in a direction from the first end portion of the tenth subtype light diffusion particle to the second end portion of the tenth subtype light diffusion particle.

20. The display device of claim 19, wherein the first subtype light diffusion particle is selected from a rod-shaped particle, the second subtype light diffusion particle is selected from an acicular particle having reduced diameters from middle to an end, the third subtype light diffusion particle is selected from an acicular particle having reduced diameters from middle to both ends, the fourth subtype light diffusion particle is selected from a long cone-shaped particle, the fifth subtype light diffusion particle is selected from a bicone-shaped particle and/or an ellipsoid-shaped particle, the sixth subtype light diffusion particle is selected from a cubic particle or a cuboid-shaped particle, the seventh subtype light diffusion particle is selected from a spherical particle or an ellipsoid-shaped particle, the eighth subtype light diffusion particle is selected from an acicular particle having reduced diameters from middle to an end, the ninth subtype light diffusion particle is selected from an acicular particle having reduced diameters from middle to both ends, and the tenth subtype light diffusion particle is selected from a long cone-shaped particle.
